(19) United States
(12) Patent Application Publication
(10) Pub. No.: US 2022/0382953 A1
(43) Pub. Date: Dec. 1, 2022

(54) SYSTEM AND METHOD FOR PERFORMING REFLOW MODELING IN A VIRTUAL FABRICATION ENVIRONMENT

(71) Applicant: Coventor, Inc., Cary, NC (US)

(72) Inventors: Qing Peng Wang, Shanghai (CN); Yu De Chen, Tainan City (TW); Shi-hao Huang, Kaohsiung City (TW); Joseph Ervin, San Jose, CA (US); Rui Bao, Shanghai (CN)

(21) Appl. No.: 17/775,197

(22) PCT Filed: Nov. 3, 2020
(86) PCT No.: PCT/US2020/058651

§ 371 Date: May 6, 2022

(30) Foreign Application Priority Data
Nov. 7, 2019 (CN) 201911080720.2

(51) Int. Cl. G06F 30/398

(52) U.S. Cl. CPC G06F 30/398

(57) ABSTRACT

Systems and methods for performing reflow modeling in a virtual fabrication environment are discussed. More particularly, the virtual fabrication environment may determine metal or material “reflow” or movement during fabrication of a semiconductor device structure. A reflow modeling step with user-specified parameters may be inserted into a process sequence used during fabrication of the semiconductor device structure.

### RELATED APPLICATION

This application claims priority to Chinese Patent Application No. 201911080720.2, filed Nov. 7, 2019 and entitled “System and Method for Performing Reflow Modeling in a Virtual Fabrication Environment”, the entire content of which is incorporated herein by reference.

### BACKGROUND

Semiconductor development organizations at integrated device manufacturers (IDMs) and independent foundries spend significant resources developing the integrated sequence of process operations used to fabricate the chips (integrated circuits (ICs)) they sell from wafers (“wafers” are thin slices of semiconductor material, frequently, but not always, composed of silicon crystal). A large portion of the resources is spent on fabricating experimental wafers and associated measurement, metrology (“metrology” refers to specialized types of measurements conducted in the semiconductor industry) and characterization structures, all for the purpose of ensuring that the integrated process produces the desired semiconductor device structures. These experimental wafers are used in a trial-and-error scheme to develop individual processes for the fabrication of a device structure and also to develop the total, integrated process flow. Due to the increasing complexity of advanced technology node process flows, a large portion of the experimental fabrication runs result in negative or null characterization results. These experimental runs are long in duration, weeks to months in the “fab” (fabrication environment), and expensive. Recent semiconductor technology advances, including FinFET, TriGate, High-K/Metal-Gate, embedded memories and advanced patterning, have dramatically increased the complexity of integrated semiconductor fabrication processes. The cost and duration of technology development using this trial-and-error experimental methodology has concurrently increased.

A virtual fabrication environment for semiconductor device structures offers a platform for performing semiconductor process development at a lower cost and higher speed than is possible with conventional trial-and-error physical experimentation. In contrast to conventional CAD and TCAD environments, a virtual fabrication environment is capable of virtually modeling an integrated process flow and predicting the complete 3D structures of all devices and circuits that comprise a full technology suite. Virtual fabrication can be described in its most simple form as combining a description of an integrated process sequence with a subject design, in the form of 2D design data (masks or layout), and producing a 3D structural model that is predictive of the result expected from a real/physical fabrication run. A 3D structural model includes the geometrically accurate 3D shapes of multiple layers of materials, implants, diffusions, etc. that comprise a chip or a portion of a chip. Virtual fabrication is done in a way that is primarily geometric, however the geometry involved is instructed by the physics of the fabrication processes. By performing the modeling at the structural level of abstraction (rather than physics-based simulations), construction of the structural models can be dramatically accelerated, enabling full technology modeling, at a circuit-level area scale. The use of a virtual fabrication environment thus provides fast verification of process assumptions, and visualization of the complex interrelationship between the integrated process sequence and the 2D design data.

### BRIEF SUMMARY

Embodiments of the present invention provide the ability to perform reflow modeling in a virtual fabrication environment. More particularly, embodiments enable the virtual fabrication environment to model metal reflow to refill an unexpected seam or void occurring during metal deposition in a small trench or via. Embodiments also enable the simulation of metal reflow for bump/solder ball formation. Embodiments additionally enable the virtual fabrication environment to model material reflow to smooth material surfaces such as when fabricating a round Si nanowire.

In one embodiment, a computing device-implemented method for performing reflow modeling in a virtual fabrication environment includes the step of receiving a selection of a process sequence in a process editor for a semiconductor device structure to be virtually fabricated, the process sequence including a user-specified reflow modeling step. The reflow modeling step indicates a point during the process sequence for reflow modeling to be performed. The method further performs with the computing device a virtual fabrication run that models an integrated process flow used to physically fabricate the semiconductor device structure by using the process sequence and 2D design data to simulate patterning, material addition and/or material removal steps performed to physically fabricate the semiconductor device structure. The virtual fabrication run executes the process sequence up until the reflow modeling step and builds a 3D structural model of the semiconductor device structure. The 3D structural model is predictive of a result of a physical fabrication of the semiconductor device structure. The virtual fabrication run further performs the reflow modeling step within a region of the 3D structural model which generates reflow data. The reflow modeling step also outputs the reflow data.

In another embodiment, a system for performing reflow modeling in a virtual fabrication environment includes a system for performing reflow modeling in a virtual fabrication environment. The system includes at least one materials database. The system further includes at least one computing device equipped with one or more processors and configured to generate a virtual fabrication environment that includes a reflow modeling module. The reflow modeling module when executed receives a selection of a process sequence in a process editor for a semiconductor device structure to be virtually fabricated. The process sequence includes a user-specified reflow modeling step that indicates a point during the process sequence for reflow modeling to be performed. The reflow modeling module when executed further performs with the computing device a virtual fabrication run that models an integrated process flow used to physically fabricate the semiconductor device structure by using the process sequence and 2D design data to simulate patterning, material addition and/or material removal steps performed to physically fabricate the semiconductor device structure. The virtual fabrication run executes the process sequence up until the reflow modeling step. The executing of the process sequence builds a 3D structural model of the semiconductor device structure using data from the materials database. The 3D structural model is predictive of a result of a physical fabrication of the semiconductor device structure. The virtual fabrication run further performs the reflow modeling step within a region of the 3D structural model which generating reflow data. The reflow modeling step also outputs the reflow data.

### BRIEF DESCRIPTION OF THE DRAWINGS

The accompanying drawings, which are incorporated in and constitute a part of this specification, illustrate one or more embodiments of the invention and, together with the description, help to explain the invention. In the drawings:

FIG. 1 depicts an exemplary virtual fabrication environment suitable for practicing an embodiment of the present invention;

FIG. 2 depicts an exemplary virtual fabrication console provided by the virtual fabrication environment;

FIG. 3 depicts an exemplary layout editor provided by the virtual fabrication environment;

FIG. 4 depicts an exemplary process editor provided by the virtual fabrication environment;

FIG. 5 depicts an exemplary 3D viewer provided by the virtual fabrication environment;

FIG. 6 depicts an exemplary sequence of steps performed in the virtual fabrication environment to set up and perform a virtual experiment generating virtual metrology measurement data for multiple semiconductor device structure models;

FIG. 7 depicts an exemplary parameter explorer view used to provide process parameters for a virtual experiment provided by the virtual fabrication environment;

FIG. 8 depicts an exemplary tabular-formatted display of virtual metrology data generated in a virtual experiment provided by the virtual fabrication environment;

FIG. 9 depicts an exemplary graphical display of virtual metrology data generated in a virtual experiment provided by the virtual fabrication environment;

FIG. 10A depicts exemplary voxel-based representations of a circle boundary;

FIG. 10B depicts exemplary staircasing effects addressed by adjusting voxel size;

FIG. 11 depicts an exemplary void from metal deposition in a trench occurring during semiconductor device fabrication;

FIG. 12 depicts a sequence for modeling metal reflow in an exemplary embodiment;

FIG. 13A provides a graphical depiction of the effect of modeling material reflow in an exemplary embodiment;

FIG. 13B provides a graphical depiction of the effect of modeling material reflow for an Si nanowire in an exemplary embodiment;

FIG. 14 depicts a voxel numpy array that corresponds to a portion of a 3D model with a trench containing a void in metal following a deposition step in an exemplary embodiment;

FIG. 15 depicts an exemplary interface recognition performed in an exemplary embodiment;

FIGS. 16A-D depict exemplary surface curvature calculations performed during reflow modeling in an exemplary embodiment;

FIG. 16E depicts an exemplary graphical user interface for accepting a contact angle parameter in an exemplary embodiment;

FIG. 16F is an exemplary depiction of a capillary effect in a device structure model using multiple contact angles during reflow in an exemplary embodiment;

FIGS. 17A-B depict exemplary net recognition operations performed during reflow modeling in an exemplary embodiment;

FIG. 18A depicts voxel replacement performed in an exemplary embodiment;

FIG. 18B depicts reflow merger and movement attainable by setting different contact angles in an exemplary embodiment;

FIG. 18C depicts the effect of performing reflow based on net surface area in an exemplary embodiment;

FIG. 19 depicts exemplary user interfaces suitable for adding reflow modeling steps to a process sequence and selecting parameters for the material reflow of FIGS. 13A and 13B;

FIG. 20 depicts exemplary metal reflow modeled for solder/ball formation in an exemplary embodiment;

FIG. 21 depicts an exemplary user interface suitable for selecting parameters for the solder/ball formation of FIG. 20;

FIG. 22 depicts exemplary DOE results for solder/ball formation in an exemplary embodiment;

FIG. 23 depicts a sequence of steps performed in the virtual fabrication environment to perform reflow modeling in an exemplary embodiment; and

FIGS. 24A-B depict local distance control in an exemplary embodiment;

FIG. 24C depicts a result of a DOE showing the effect of local distance control while performing reflow in an exemplary embodiment;

FIG. 24D depicts an exemplary graphical user interface for accepting a local distance control parameter in an exemplary embodiment;

FIG. 25A graphically depicts the effect of gravity during reflow;

FIG. 25B depicts exemplary gravity effect calculations in an exemplary embodiment;

FIG. 25C depicts an exemplary graphical user interface for accepting a gravity parameter in an exemplary embodiment; and

FIG. 25D depicts a result of a DOE showing the effect of the use of a gravity parameter while performing reflow in an exemplary embodiment.

### DETAILED DESCRIPTION

Semiconductor device fabrication typically includes large numbers of patterning steps and material addition and removal steps that occur in a carefully organized sequence as part of the fabrication process. Reflow operations may be used during fabrication to correct errors and/or to better achieve a desired result from a step in a process sequence by providing thermal energy to metal or other material to cause the metal or other material to “reflow” to a desired condition. As one example of the use of reflow operations during semiconductor device fabrication, metal deposition fill in a small trench or via well will sometimes form an unexpected seam/void in the small trench or via. “Reflow” may be introduced to give the metal a thermal energy to refill the trench or via. Similarly, bump/solder ball formation are important processes during chip package, and one of the key steps is to heat the metal and let it “reflow” to finally obtain the bump shape. In addition, material “reflow” to smooth material surfaces is also an important application in advanced node. For instance, in Si nanowire formation in a Gate All Around (GAA) process, E-field crowding due to square-shaped Si nanowire is a major concern. Si “reflow” may be introduced to generate a rounded Si nanowire. Additional uses of reflow include display applications for lense formation with thermal reflow and planarization material and thermal reflow to smooth a surface. Unfortunately, reflow is a highly complicated process with abstruse physics and has therefore conventionally not been well-suited to modeling in a virtual fabrication environment.

Embodiments of the present invention provide a virtual fabrication environment enabling reflow modeling as part of a process sequence. However, prior to discussing the reflow modeling provided by embodiments in greater detail, an exemplary 3D virtual fabrication environment which may be utilized to practice the embodiments is first described.

Exemplary Virtual Fabrication Environment

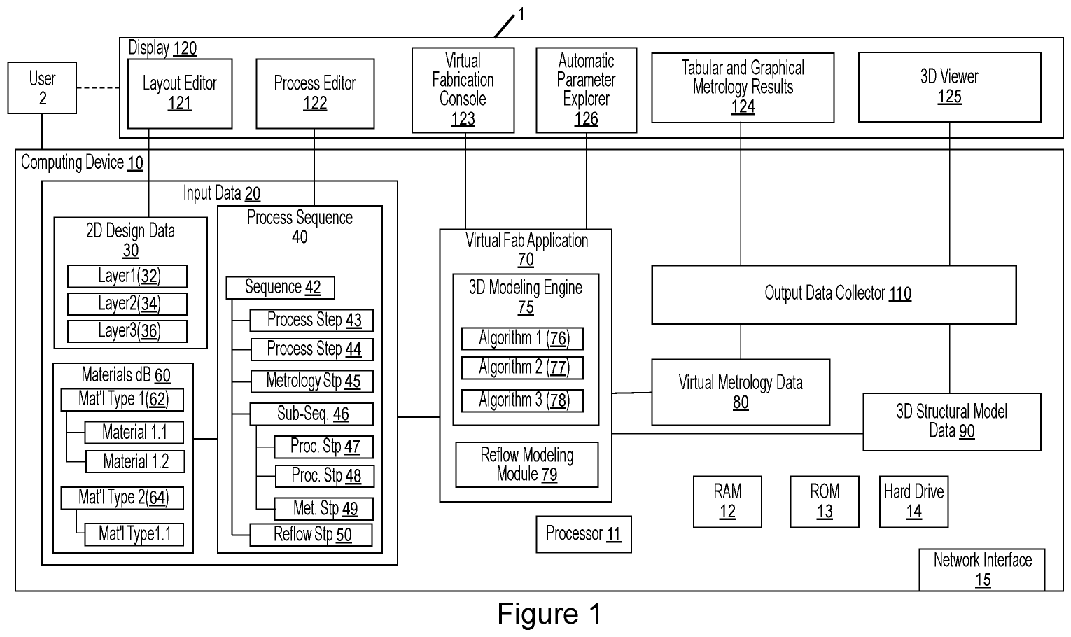

FIG. 1 depicts an exemplary virtual fabrication environment 1 suitable for practicing an embodiment of the present invention. Virtual fabrication environment 1 includes a computing device 10 accessed by a user 2. Computing device 10 is in communication with a display 120. Display 120 may be a display screen that is part of computing device 10 or may be a separate display device or display surface in communication with computing device 10. Computing device 10 may be a PC, laptop computer, tablet computing device, server, or some other type of computing device equipped with a processor 11 and able to support the operations of 3D modeling engine 75 (described further below). The processor may have one or more cores. The computing device 10 may also include volatile and non-volatile storage such as, but not limited to, Random Access Memory (RAM) 12, Read Only Memory (ROM) 13 and hard drive 14. Computing device 10 may also be equipped with a network interface 15 so as to enable communication with other computing devices.

Computing device 10 may store and execute virtual fabrication application 70 including 3D modeling engine 75. 3D modeling engine 75 may include one or more algorithms such as algorithm 1 (76), algorithm 2 (77), and algorithm 3 (78) used in virtually fabricating semiconductor device structures. Virtual fabrication application 70 may also include reflow modeling module 79 containing executable instructions for modeling reflow operations. 3D modeling engine 75 may accept input data 20 in order to perform virtual fabrication “runs” that produce semiconductor device structural model data 90. Virtual fabrication application 70 and 3D modeling engine 75 may generate a number of user interfaces and views used to create and display the results of virtual fabrication runs. For example, virtual fabrication application 70 and 3D modeling engine 75 may display layout editor 121, process editor 122 and virtual fabrication console 123 used to create virtual fabrication runs. Virtual fabrication application 70 and 3D modeling engine 75 may also display a tabular and graphical metrology results view 124 and 3D view 125 for respectively displaying results of virtual fabrication runs and 3D structural models generated by the 3D modeling engine 75 during virtual fabrication of semiconductor device structures.

Input data 20 includes both 2D design data 30 and process sequence 40. Process sequence 40 may be composed of multiple process steps 43, 44, 47, 48 and 49. As described further herein, process sequence 40 may also include one or more virtual metrology measurement process steps 45. Process sequence 40 may further include one or more subsequences which include one or more of the process steps or virtual metrology measurement process steps. 2D design data 30 includes of one or more layers such as layer 1 (32), layer 2 (34) and layer 3 (36), typically provided in an industry-standard layout format such as GDS II (Graphical Design System version 2) or OASIS (Open Artwork System Interchange Standard).

Input data 20 may also include a materials database 60 including records of material types such as material type 1 (62) and material type 2 (64) and specific materials for each material type. Many of the process steps in a process sequence may refer to one or more materials in the materials database. Each material has a name and some attributes such as a rendering color. The materials database may be stored in a separate data structure. The materials database may have hierarchy, where materials may be grouped by types and sub-types. Individual steps in the process sequence may refer to an individual material or a parent material type. The hierarchy in the materials database enables a process sequence referencing the materials database to be modified more easily. For example, in virtual fabrication of a semiconductor device structure, multiple types of oxide material may be added to the structural model during the course of a process sequence. After a particular oxide is added, subsequent steps may alter that material. If there is no hierarchy in the materials database and a step that adds a new type of oxide material is inserted in an existing process sequence, all subsequent steps that may affect oxide materials must also be modified to include the new type of oxide material. With a materials database that supports hierarchy, steps that operate on a certain class of materials such as oxides may refer only to the parent type rather than a list of materials of the same type. Then, if a step that adds a new type of oxide material is inserted in a process sequence, there is no need to modify subsequent steps that refer only to the oxide parent type. Thus hierarchical materials make the process sequence more resilient to modifications. A further benefit of hierarchical materials is that stock process steps and sequences that refer only to parent material types can be created and re-used.

3D Modeling Engine 75 uses input data 20 to perform the sequence of operations/steps specified by process sequence 40. As explained further below, process sequence 40 may include one or more virtual metrology steps 45, 49 that indicate a point in the process sequence during a virtual fabrication run at which a measurement of a structural component should be taken. The measurement may be taken using a locator shape previously added to a layer in the 2D design data 30. In an alternative embodiment the measurement location may be specified by alternate means such as (x, y) coordinates in the 2D design data or some other means of specifying a location in the 2D design data 30 instead of through the use of a locator shape. Process sequence may also include one or more reflow modeling steps 50 that indicate a point in the process sequence during a virtual fabrication run at which a reflow modeling operation should be performed. The performance of the process sequence 40 during a virtual fabrication run generates virtual metrology data 80 and 3D structural model data 90. 3D structural model data 90 may be used to generate a 3D view of the structural model of the semiconductor device structure which may be displayed in the 3D viewer 125. Virtual metrology data 80 may be processed and presented to a user 2 in the tabular and graphical metrology results view 124.

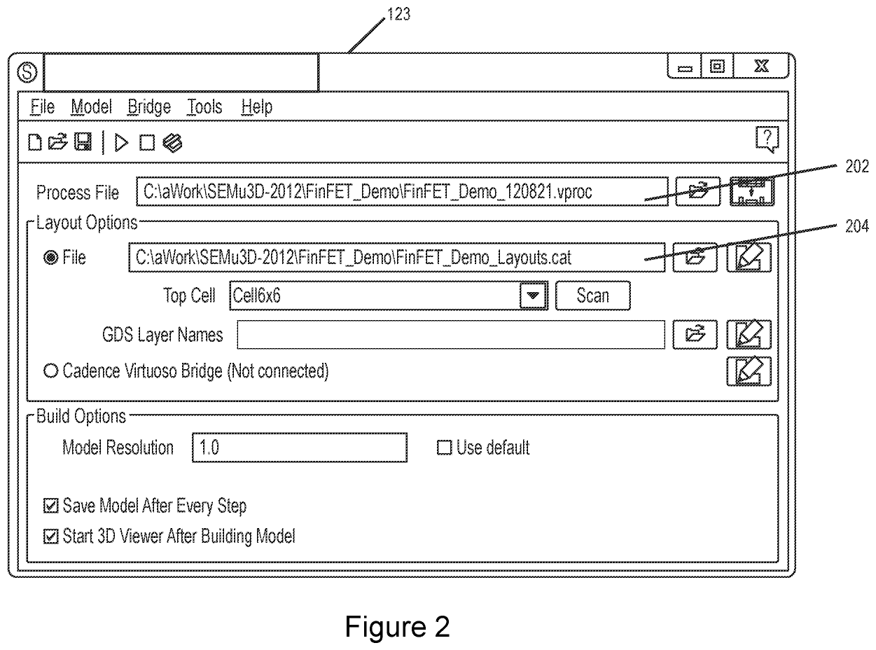

FIG. 2 depicts an exemplary virtual fabrication console 123 provided by the virtual fabrication environment to set up a virtual fabrication run. The virtual fabrication console 123 allows the user to specify a process sequence 202 and the layout (2D design data) 204 for the semiconductor device structure that is being virtually fabricated. It should be appreciated however that the virtual fabrication console can also be a text-based scripting console that provides the user with a means of entering scripting commands that specify the required input and initiate building of a structural model, or building a set of structural models corresponding to a range of parameter values for specific steps in the process sequence. The latter case is considered a virtual experiment (discussed further below).

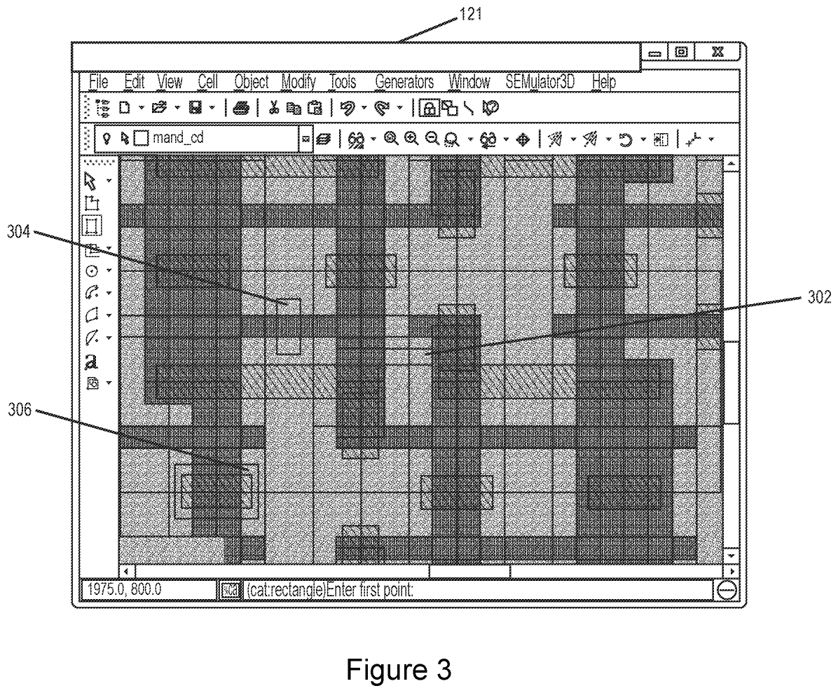

FIG. 3 depicts an exemplary layout editor provided by the virtual fabrication environment. The layout editor 121 displays the 2D design layout specified by the user in the virtual fabrication console 123. In the layout editor, color may be used to depict different layers in the design data. The areas enclosed by shapes or polygons on each layer represent regions where a photoresist coating on a wafer may be either exposed to light or protected from light during a photolithography step in the integrated process flow. The shapes on one or more layers may be combined (booleaned) to form a mask that is used in a photolithography step. The layout editor 121 provides a means of inserting, deleting and modifying a polygon on any layer, and of inserting, deleting or modifying layers within the 2D design data. A layer can be inserted for the sole purpose of containing shapes or polygons that indicate the locations of virtual metrology measurements. The rectangular shapes 302, 304, 306 have been added to an inserted layer (indicated by a different color) and mark the locations of virtual metrology measurements. As noted above, other approaches to specifying the locations for the virtual metrology measurements besides the use of locator shapes should also be considered within the scope of the present invention. The design data is used in combination with the process data and materials database to build a 3D structural model.

Inserted layers in the design data displayed in the layout editor 121 may include inserted locator shapes. For example, a locator shape may be a rectangle, the longer sides of which indicate the direction of the measurement in the 3D structural model. For example, in FIG. 3, a first locator shape 302 may mark a double patterning mandrel for virtual metrology measurement, a second locator shape 304 may mark a gate stack for virtual metrology measurement and a third locator shape 306 may mark a transistor source or drain contact for virtual metrology measurement

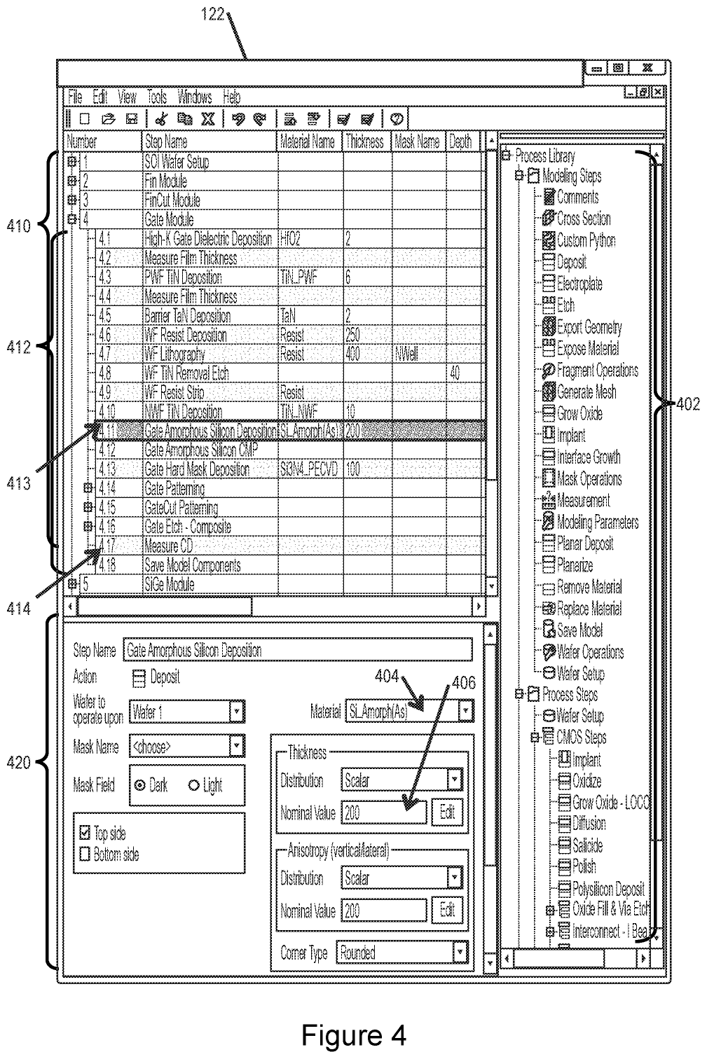

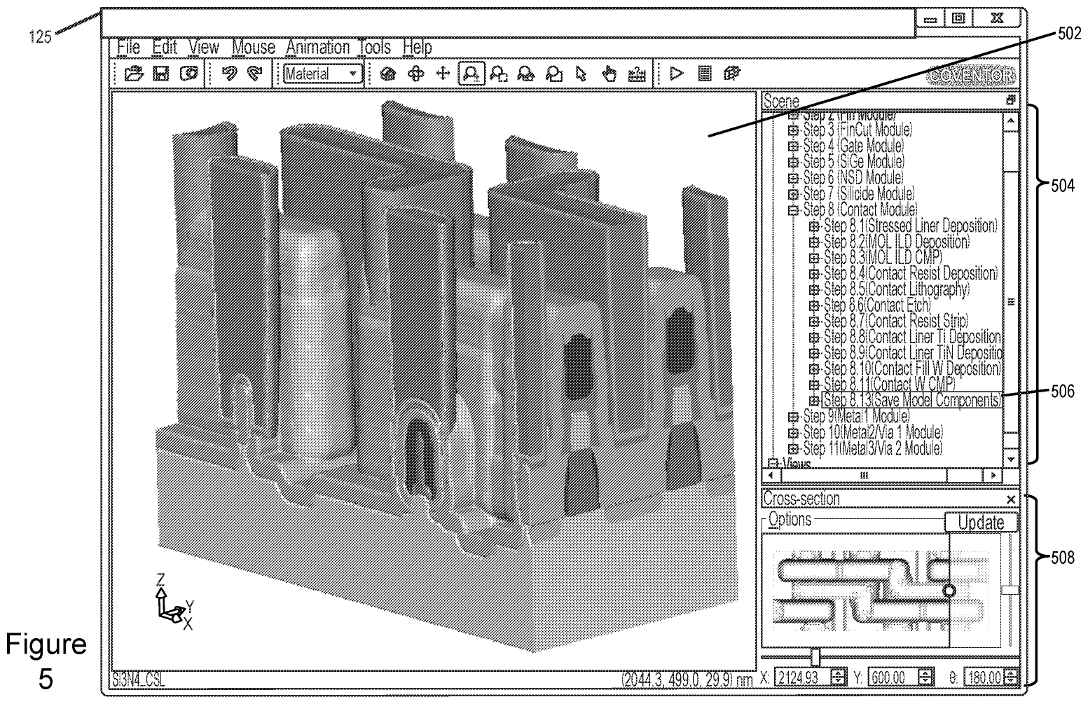

FIG. 4 depicts an exemplary process editor 122 provided by the virtual fabrication environment. The user defines a process sequence in the process editor. The process sequence is an ordered list of process steps conducted in order to virtually fabricate the user's selected structure. The process editor may be a text editor, such that each line or group of lines corresponds to a process step, or a specialized graphical user interface such as is depicted in FIG. 4. The process sequence may be hierarchical, meaning process steps may be grouped into sub-sequences and sub-sequences of sub-sequences, etc. Generally, each step in the process sequence corresponds to an actual step in the fab. For instance, a sub-sequence for a reactive ion etch operation might include the steps of spinning on photo resist, patterning the resist, and performing the etch operation. The user specifies parameters for each step or sub-step that are appropriate to the operation type. Some of the parameters are references to materials in the materials database and layers in the 2D design data. For example, the parameters for a deposit operation primitive are the material being deposited, the nominal thickness of the deposit and the anisotropy or ratio of growth in the lateral direction versus the vertical direction. This deposit operation primitive can be used to model actual processes such as chemical vapor deposition (CVD). Similarly, the parameters for an etch operation primitive are a mask name (from the design data), a list of materials affected by the operation, and the anisotropy.

There may be hundreds of steps in the process sequence and the process sequence may include sub-sequences. For example, as depicted in FIG. 4, a process sequence 410 may include a subsequence 412 made up of multiple process steps such as selected step 413. The process steps may be selected from a library of available process steps 402. For the selected step 413, the process editor 122 enables a user to specify all required parameters 420. For example, a user may be able to select a material from a list of materials in the material database 404 and specify a process parameter 406 for the material's use in the process step 413.

One or more steps in the process sequence may be virtual metrology steps inserted by a user. For example, the insertion of step 4.17 “Measure CD” (414), where CD denotes a critical dimension, in process sequence 412 would cause a virtual metrology measurement to be taken at that point in the virtual fabrication run using one or more locator shapes that had been previously inserted on one or more layers in the 2D design data. By inserting the virtual metrology steps directly in the fabrication sequence, the embodiment of the present invention allows virtual metrology measurements to be taken at critical points of interest during the fabrication process. As the many steps in the virtual fabrication interact in the creation of the final structure, the ability to determine geometric properties of a structure, such as cross-section dimensions and surface area, at different points in the integrated process flow is of great interest to the process developer and structure designer.

FIG. 5 depicts an exemplary 3D viewer 125 provided by the virtual fabrication environment. The 3D viewer 75 may include a 3D view canvas 502 for displaying 3D models generated by the 3D modeling engine 75. The 3D viewer 75 may display saved states 504 in the process sequence and allow a particular state to be selected 506 and appear in the 3D view canvas. The 3D Viewer provides functionality such as zoom in/out, rotation, translation, cross section, etc. Optionally, the user may activate a cross section view in the 3D view canvas 502 and manipulate the location of the cross section using a miniature top view 508.

While building a single structural model can be valuable, there is increased value in virtual fabrication that builds a large number of models. The virtual fabrication environment enables a user to create and run a virtual experiment. In a virtual experiment of the present invention, a range of values of process parameters can be explored. A virtual experiment may be set up by specifying a set of parameter values to be applied to individual processes (rather than a single value per parameter) in the full process sequence. A single process sequence or multiple process sequences can be specified this way. The 3D modeling engine 75, executing in virtual experiment mode, then builds multiple models spanning the process parameter set, all the while utilizing the virtual metrology measurement operations described above to extract metrology measurement data for each variation. This capability provided by the embodiments of the present invention may be used to mimic two fundamental types of experiments that are typically performed in the physical fab environment. Firstly, fabrication processes vary naturally in a stochastic (non-deterministic) fashion. As explained herein, embodiments of the present invention use a fundamentally deterministic approach for each virtual fabrication run that nevertheless can predict non-deterministic results by conducting multiple runs. The virtual experiment mode provided by an embodiment of the present invention allows the virtual fabrication environment to model through the entire statistical range of variation for each process parameter, and the combination of variations in many/all process parameters. Secondly, experiments run in the physical fab may specify a set of parameters to be intentionally varied when fabricating different wafers. The virtual experiment mode of the present invention enables the Virtual Fabrication Environment to mimic this type of experiment as well, by performing multiple virtual fabrication runs on the specific variations of a parameter set.

Each process in the fabrication sequence has its own inherent variation. To understand the effect of all the aggregated process variations in a complex flow is quite difficult, especially when factoring in the statistical probabilities of the combinations of variations. Once a virtual experiment is created, the process sequence is essentially described by the combination of numerical process parameters included in the process description. Each of these parameters can be characterized by its total variation (in terms of standard deviation or sigma values), and therefore by multiple points on a Gaussian distribution or other appropriate probability distribution. If the virtual experiment is designed and executed to examine all of the combinations of the process variations (multiple points on each Gaussian, for example the ±3 sigma, ±2 sigma, ±1 sigma, and nominal values of each parameter), then the resulting graphical and numerical outputs from virtual metrology steps in the sequence cover the total variation space of the technology. Even though each case in this experimental study is modeled deterministically by the virtual fabrication system, the aggregation of the virtual metrology results contains a statistical distribution. Simple statistical analysis, such as Root Sum Squares (RSS) calculation of the statistically uncorrelated parameters, can be used to attribute a total variation metric to each case of the experiment. Then, all of the virtual metrology output, both numerical and graphical, can be analyzed relative to the total variation metric.

In typical trial-and-error experimental practice in a physical fab, a structural measurement resulting from the nominal process is targeted, and process variations are accounted for by specifying an overly large (conservative) margin for the total variation in the structural measurement (total structural margin) which must be anticipated in subsequent processes. In contrast, the virtual experiment embodiments of the present invention can provide quantitative predictions of the total variation envelope for a structural measurement at any point in the integrated process flow. The total variation envelope, rather than the nominal value, of the structural measurement may then become the development target. This approach can ensure acceptable total structural margin throughout the integrated process flow, without sacrificing critical structural design goals. This approach, of targeting total variation may result in a nominal intermediate or final structure that is less optimal (or less aesthetically pleasing) than the nominal structure that would have been produced by targeting the nominal process. However, this sub-optimal nominal process is not critical, since the envelope of total process variation has been accounted for and is more important in determining the robustness and yield of the integrated process flow. This approach is a paradigm shift in semiconductor technology development, from an emphasis on the nominal process to an emphasis on the envelope of total process variation.

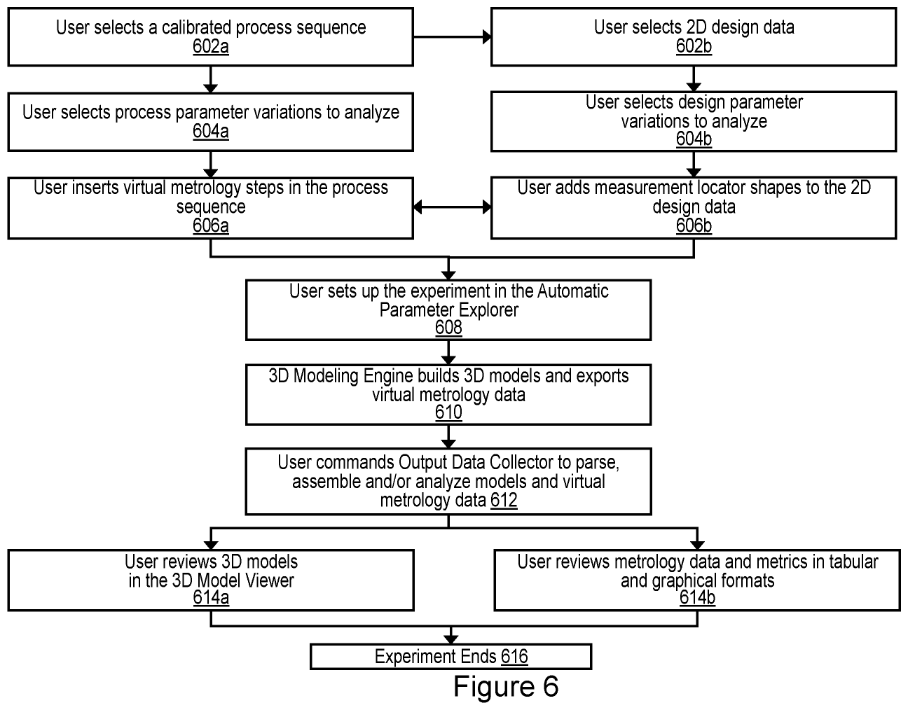

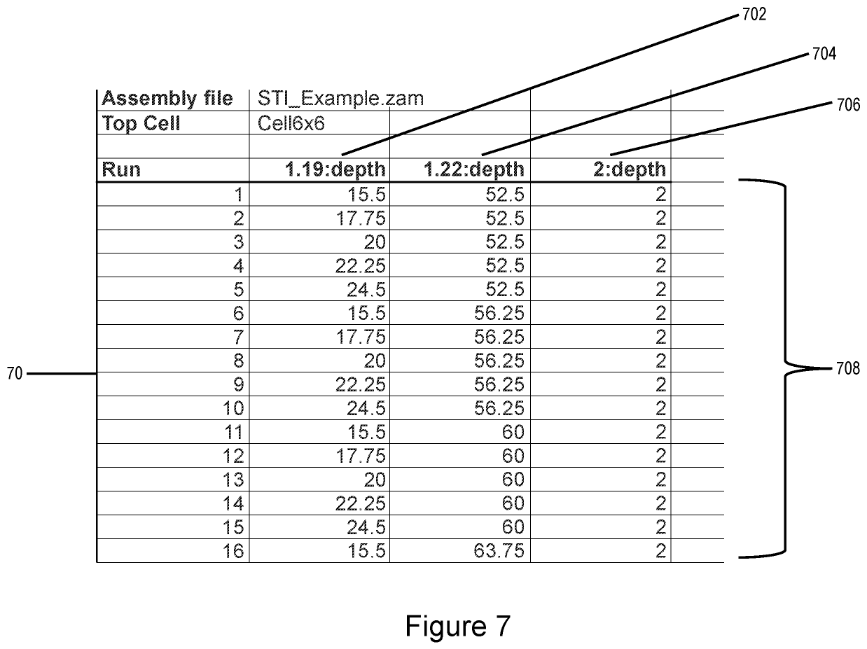

FIG. 6 depicts an exemplary sequence of steps that may be performed in the virtual fabrication environment to set up and perform a virtual experiment generating virtual metrology measurement data for multiple semiconductor device structural models. The sequence begins with a user selecting a process sequence (which may have been previously calibrated to make the results more structurally predictive (step 602a) and identifying/creating 2D design data (step 602b). The user may select process parameter variations to analyze (step 604a) and/or design parameter variations to analyze (step 604b). The user inserts one or more virtual metrology steps in the process sequence as set forth above (step 606a) and adds measurement locator shapes to the 2D design data (step 606b). The user may set up the virtual experiment with the aid of a specialized user interface, an automatic parameter explorer 126 (step 608). An exemplary automatic parameter explorer is depicted in FIG. 7 and may display, and allow the user to vary, the process parameters to be varied 702, 704, 706 and the list of 3D models to be built with their corresponding different parameter values 708. The parameter ranges for a virtual experiment can be specified in a tabular format. The 3D modeling engine 75 builds the 3D models and exports the virtual metrology measurement data for review (step 610). The virtual experiment mode provides output data handling from all Virtual Measurement/Metrology operations. The output data from the virtual metrology measurements may be parsed and assembled into a useful form (step 612).

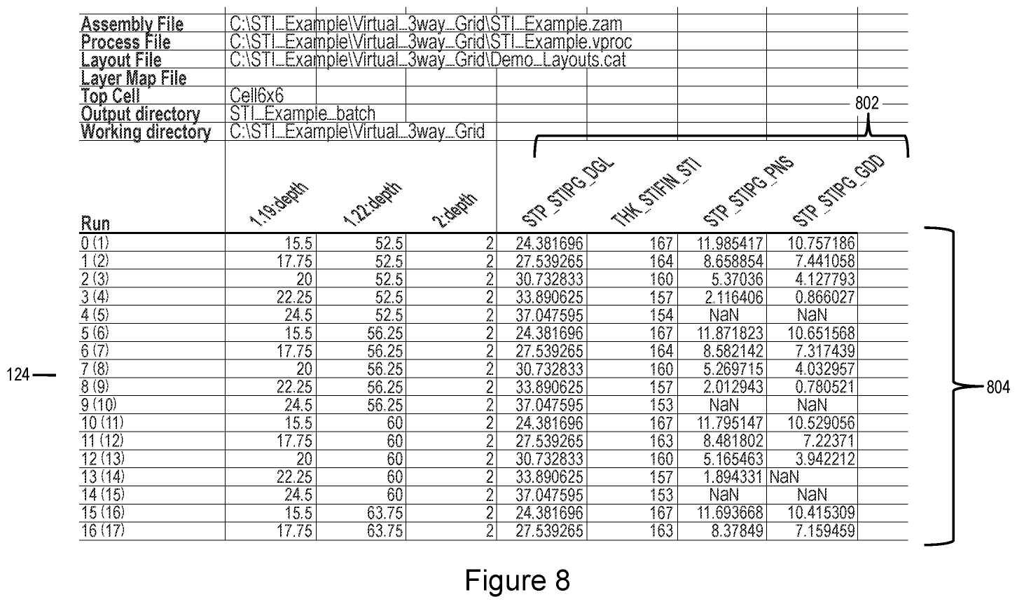

With this parsing and assembling, subsequent quantitative and statistical analysis can be conducted. A separate output data collector module 110 may be used to collect 3D model data and virtual metrology measurement results from the sequence of virtual fabrication runs that comprise the virtual experiment and present them in graphical and tabular formats. FIG. 8 depicts an exemplary tabular-formatted display of virtual metrology data generated by a virtual experiment. In the tabular formatted display, the virtual metrology data collected during the virtual experiment 802 and the list of virtual fabrication runs 804 may be displayed.

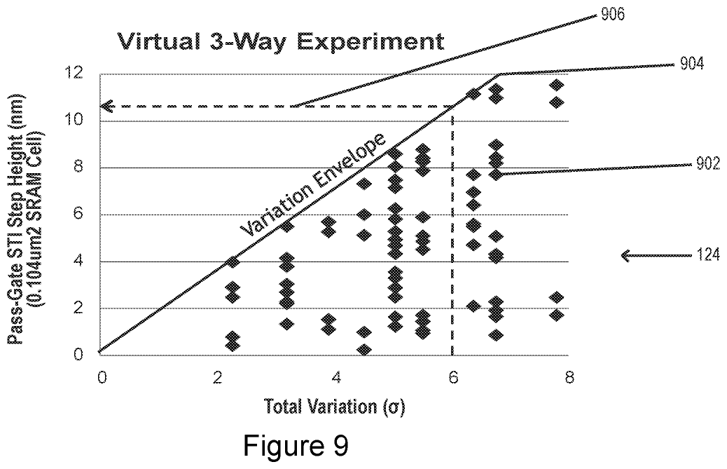

FIG. 9 depicts an exemplary 2D X-Y graphical plot display of virtual metrology data generated by a virtual experiment. In the example depicted in FIG. 7, the total variation in shallow trench isolation (STI) step height due to varying 3 parameters in preceding steps of the process sequence is shown. Each diamond 902 represents a virtual fabrication run. The variation envelope 904 is also displayed as is the depicted conclusion 906 that the downstream process modules must support approximately 10.5 nm of total variation in STI step height to achieve robustness through 6 sigma of incoming variation. The virtual experiment results can also be displayed in multi-dimensional graphic formats.

Once the results of the virtual experiment have been assembled, the user can review 3D models that have been generated in the 3D viewer (step 614a) and review the virtual metrology measurement data and metrics presented for each virtual fabrication run (step 614b). Depending on the purpose of the virtual experiment, the user can analyze the output from the 3D modeling engine for purposes of developing a process sequence that achieves a desired nominal structural model, for further calibrating process step input parameters, or for optimizing a process sequence to achieve a desired process window.

The 3D modeling engine's 75 task of constructing multiple structural models for a range of parameter values (comprising a virtual experiment) is very compute intensive and therefore could require a very long time (many days or weeks) if performed on a single computing device. To provide the intended value of virtual fabrication, model building for a virtual experiment must occur many times faster than a physical experiment. Achieving this goal with present day computers requires exploiting any and all opportunities for parallelism. The 3D modeling engine 75 of the present invention uses multiple cores and/or processors to perform individual modeling steps. In addition, the structural models for different parameter values in a set are completely independent and can therefore be built in parallel using multiple cores, multiple processors, or multiple systems.

3D modeling engine 75 may represent the underlying structural model using a voxel-based implicit geometry representation. Voxels are essentially 3D pixels. Each voxel is a cube of the same size, and may contain one or more materials, or no materials. An implicit geometry representation is one in which the interface between materials in the 3D structural model are defined without an explicit representation of the (x,y,z) coordinate locations of that interface. Many of the operations performed by the 3D modeling engine are voxel modeling operations. Modeling operations based on a digital voxel representation are far more robust than the corresponding operations in a conventional analog solid modeling kernel (e.g. a NURBS-based solid modeling kernel). Such solid modeling kernels generally rely on a large number of heuristic rules to deal with various geometric situations, and modeling operations may fail when the heuristic rules do not properly anticipate a situation. Aspects of semiconductor structural modeling that cause problems for NURBS-based solid modeling kernels include the very thin layers produced by deposition processes and propagation of etch fronts that results in merging faces and/or fragmentation of geometry.

Some simulation tools require a volume mesh to be generated from some form of explicit boundary representation and previous solutions exist for creating a volume mesh of B-rep geometry or from surface meshes. Such volume meshes for finite-element or finite-volume simulation techniques will preserve the location of the interface between materials to a high level of accuracy. Such a volume mesh is called a boundary-conforming mesh or simply a conformal mesh. A key feature of such a mesh is that no element crosses the boundary between materials. In other words, for a volume mesh of tetrahedral elements, then each element is wholly within one material and thus no tetrahedron contains more than one material. However, neither B-rep and similar solid modeling kernels, nor surface mesh representations are optimal for virtual fabrication. Solid modeling kernels generally rely on a large number of heuristic rules to deal with various geometric situations, and modeling operations may fail when the heuristic rules do not properly anticipate a situation. Geometry representations that instead represent the boundaries implicitly do not suffer from these problems. A virtual fabrication system that uses an implicit representation exclusively thus has significant advantages, even if it may not represent the interfaces as accurately.

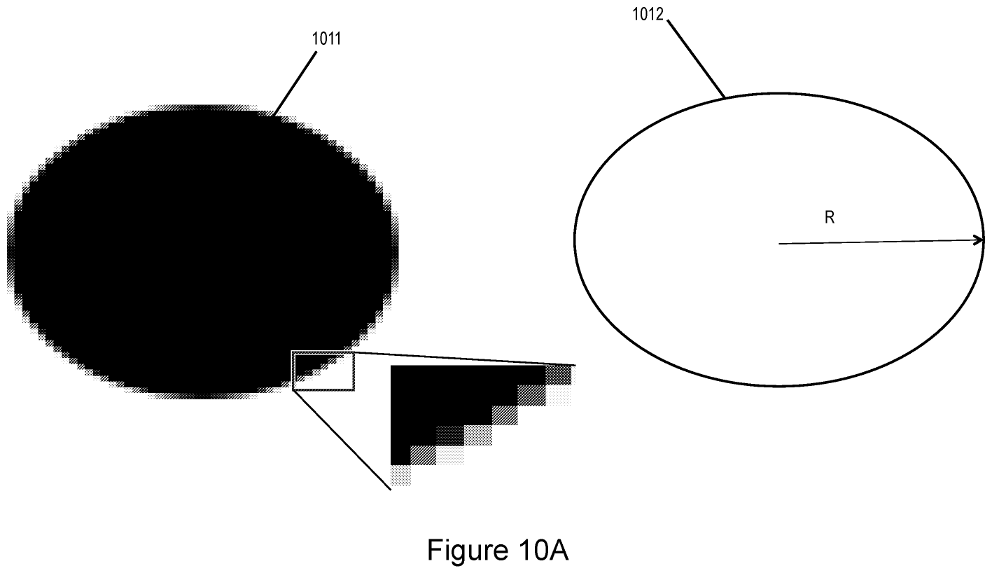

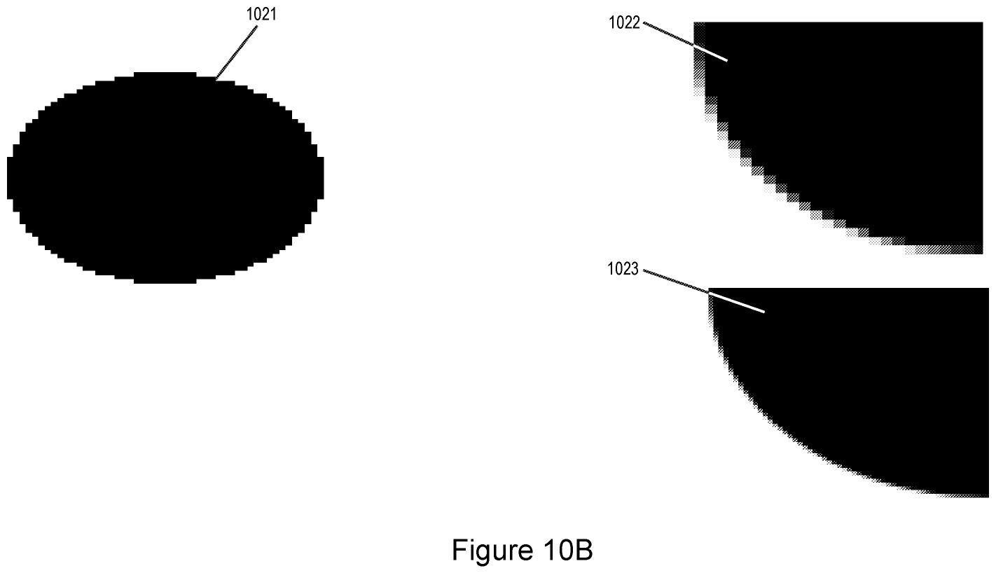

Geometric data represented with voxels implicitly represents the interface between materials. FIG. 10A illustrates this concept in two dimensions for a circle. A B-rep representation 1012 may represent the circle as the equation of a circle with radius R with material 1 inside the circle with material 2 outside. In contrast, a voxel representation of the circle 1011 is an array of cubes where each cube stores the material identification numbers within it, and the relative amounts of each material. The grayscale darkness of the squares in 1011 indicates the relative percentage of material 1 versus material 2. Black indicates 100% material 1 and 0% material 2, and white indicates 0% material 1 and 100% material 2. Since the circle cuts through the voxels along its path, grayscale voxels on the boundary of the circle are partially filled with each material and the darkness of gray indicates the fill fraction. Partially filled voxels indicate that the boundary crosses through that voxel, but does not indicate where and with what orientation. The fill fractions of a boundary voxel and others in its neighborhood may be used to determine the boundary explicitly.

Material properties at a location within the geometry are approximated using the properties of the majority material within each voxel. For instance, in an operation to determine electrical resistance if a boundary voxel is more than 50% of material 2 in circle 1011, then the bulk resistivity of material 2 is used for all values of x within that voxel, and similarly voxels of 50% or more of material 1 use bulk resistivity of material 1. This is equivalent to filling those voxels full of the majority material as shown in FIG. 10B, circle 1021. This approach incurs what is called ‘staircasing’ error in the solution over methods that explicitly know the boundary location, and thus know precisely the material at each location, x. One method to compensate for staircasing error is to decrease the size of each voxel when performing the virtual fabrication of the 3D model and thus reduce the volume of boundary voxels. For instance, circle portion 1022 is part of the circle of the voxel representation in 1011, and circle portion 1023 is the same part of the circle built with voxels one half of the size in each dimension. The volume taken up by boundary voxels is much less with the smaller voxel size and thus the error would be less. It should be noted however that decreasing the voxel size greatly increases both the virtual fabrication computation time as well as the simulation time which may lead to unacceptable results in some circumstances.

Reflow Modeling

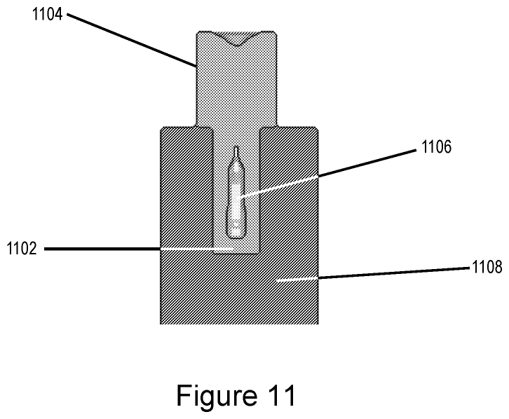

Embodiments of the present invention enable a virtual fabrication environment to behaviorally solve for metal or material “reflow” or movement as part of the virtual fabrication of a semiconductor device of interest. More particularly, embodiments enable a reflow modeling step with user-specified parameters to be inserted into a process sequence used during virtual fabrication of a semiconductor device structure. The reflow modeling may be performed to either correct errors in the fabrication process or to more efficiently achieve a desired fabrication result. Exemplary reflow uses include, without limitation, performing filling of unwanted voids or seams, solder ball formation and Si nanowire rounding. FIG. 11 depicts one such use, reflow to repair a metal void occurring as an unwanted byproduct from metal deposition in a trench during semiconductor device fabrication. As shown in FIG. 11, a small trench 1102 in a substrate 1108 has been filled with metal 1104 during a deposition step in the fabrication sequence. However, the metal deposition has inadvertently resulted in a void 1106 in the metal 1104 deposited in the trench 1102. Reflow may be used provide thermal energy to heat the metal in order to cause it to flow again (i.e. reflow), fill the void 1106, and thereby fix the defect from the deposition step. Embodiments enable the modeling of this void-filling reflow operation and other types of reflow modeling in a virtual fabrication environment.

Embodiments provide a simplified approach for liquid metal reflow modeling that does not rely on abstruse physics. The approach is based on two principals, first that liquid surface tension of liquid on the surface of an object being modeled makes the surface curvature the same everywhere, and, secondly, that if the surface curvature does have a difference, the liquid surface tension pushes out the convex surfaces while smoothing the concave surfaces. Based on these principals, in one embodiment, metal reflow modeling of a 3D model represented using a voxel-based implicit geometry representation can be performed in a virtual fabrication environment by performing interface recognition detecting an interface between materials and air in the 3D model, calculating the surface curvature of specified portions of the interface of the 3D model, performing net recognition to restrict the reflow modeling to the desired nets of the model, and performing voxel replacement for the 3D model to mimic metal reflow pushing out convex surfaces and smoothing concave surfaces.

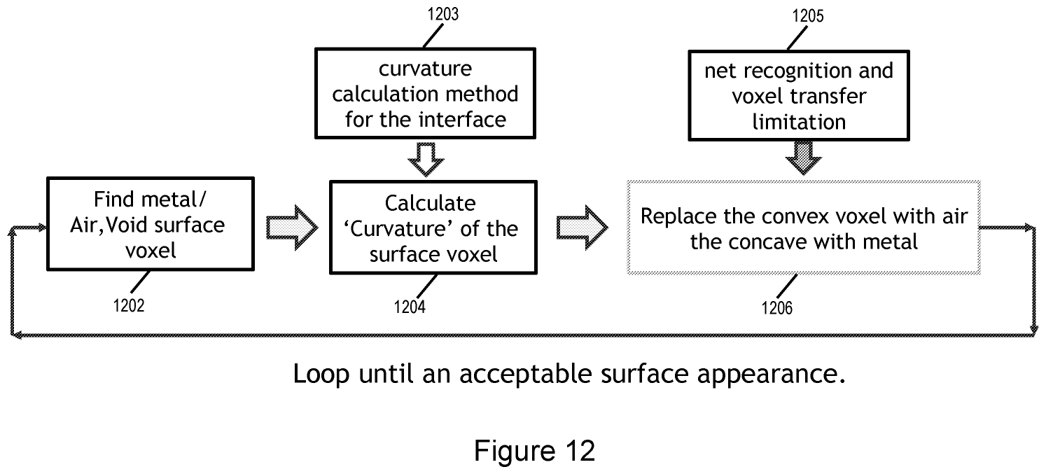

FIG. 12 depicts a sequence for modeling metal reflow in an exemplary embodiment. As discussed above, 3D structural models may be represented using voxel-based implicit geometry. Initially, voxels may be loaded to a numpy array where binaryzation/trinaryzation takes place to segment the model. Each element in the numpy array may represent metal, air/void, or other material. The sequence then begins by examining the voxel model to perform interface recognition in order to identify a metal/(air, void) surface voxel identifying those surface voxels at the intersection between metal and air (step 1202). Once identified, a curvature of the surface voxel is calculated to determine if it has a convex or concave shape (step 1204). As will be discussed further herein, metal voxel values at the convex surface areas will “flow” to the concave surface areas representing voids/seams in order to simulate the reflow process.

Bump/Solder ball formation are important processes during chip package, and one of the key steps is to heat the metal and let it “reflow” to obtain the bump shape. If the particular reflow modeling operation involves solder ball formation or a similar operation, in one embodiment the curvature calculation step may include an additional curvature calculation method (discussed further below) to identify the contact angle at the interface between the solder ball and the substrate (step 1203). Following the calculation of the curvature of the surface voxel (step 1204), a safety check is made to make sure the voxel is confined within a desired metal net (step 1205). Assuming the voxel is within the desired metal net (step 1205), voxel replacement takes place (step 1206) to simulate metal reflow to the concave areas of the model. A convex voxel with a metal value may be replaced with an air value and a concave voxel with an air value may be replaced with a metal value (to simulate metal flow). The process then loops and iterates until an acceptable surface appearance is determined, either by the virtual fabrication environment user or systematically by the reflow modeling module of the virtual fabrication environment applying pre-determined criteria. The material volume in the 3D structural model is conserved during the replacement process as the voxel values are swapped and the process does not result in voxel loss.

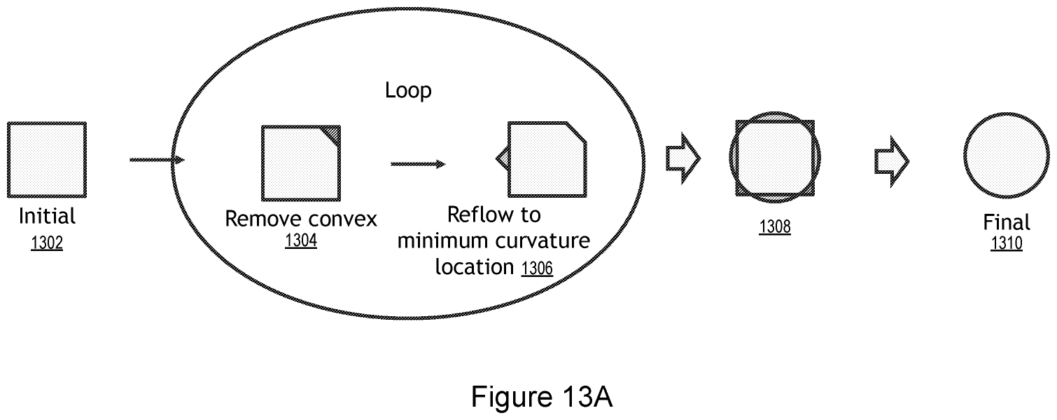

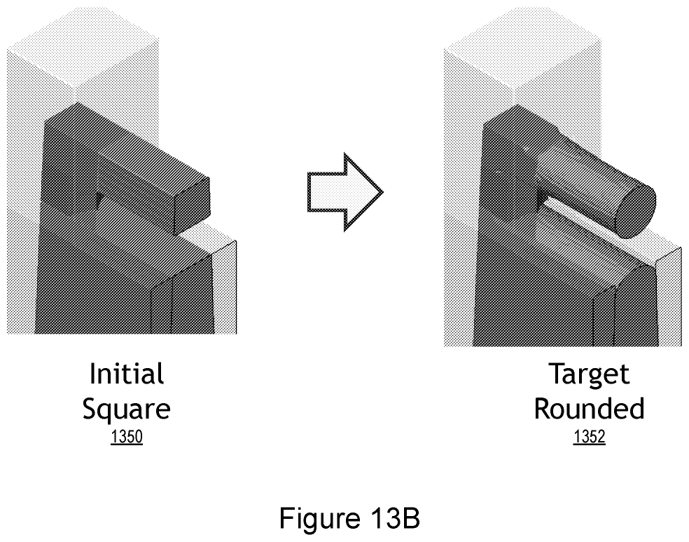

In addition to metal reflow operations to repair voids, embodiments also enable the modeling of material reflow. Material “reflow” to smooth material surfaces is an important application in advanced node. For example, in Si nanowire formation in a Gate-All-Around (GAA) process, E-field crowding due to square-shaped Si nanowire is a significant concern. Accordingly, in one embodiment, Si “reflow” may be used to generate a rounding Si nanowire. FIG. 13A provides a graphical depiction of the effect of modeling material reflow in an exemplary embodiment. The sequence begins (step 1302) with a square shaped Si nanowire. A loop may take place during fabrication to use material reflow by heating the material to iteratively remove convex portions of the Si nanowire (step 1304). Since the square-shaped Si nanowire has no obvious concave portions, the material removed from the convex portions is instead moved/reflowed to a location with a determined minimum curvature (step 1306). The loop produces a progressively rounder shape (step 1308) before eventually arriving at an acceptably rounded Si nanowire (step 1310). FIG. 13B provides another graphical depiction of the effect of modeling material reflow for an Si nanowire in an exemplary embodiment. The initial square shape 1350 is replaced by a rounded shape 1352. Further use cases for reflow modeling include, but are not limited to, display applications for lense formation with thermal reflow and the use of planarization material and thermal reflow to smooth a surface.

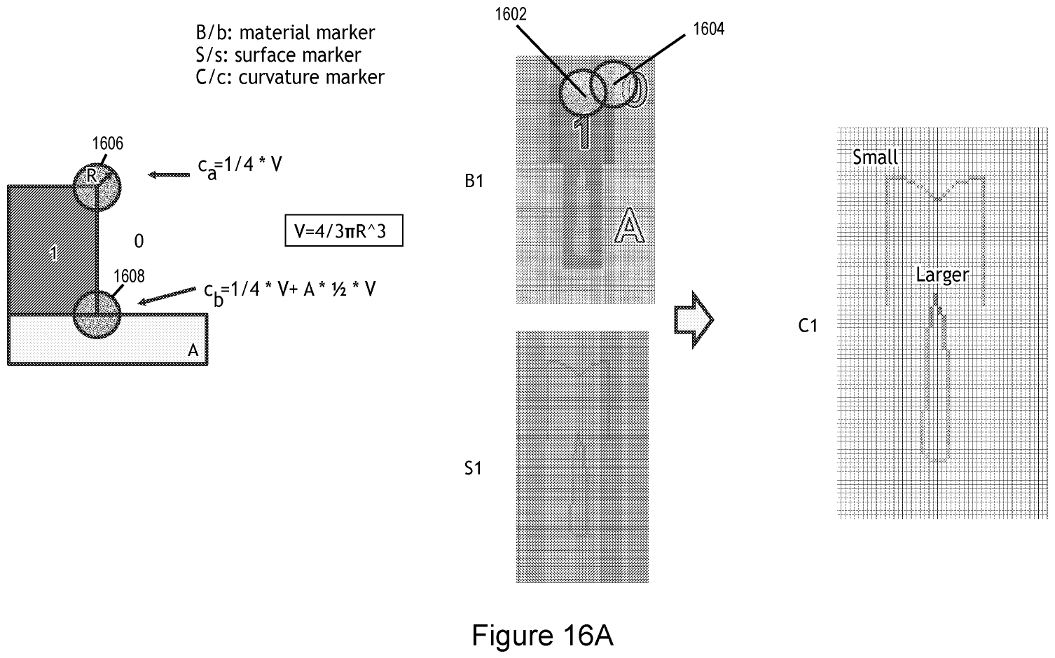

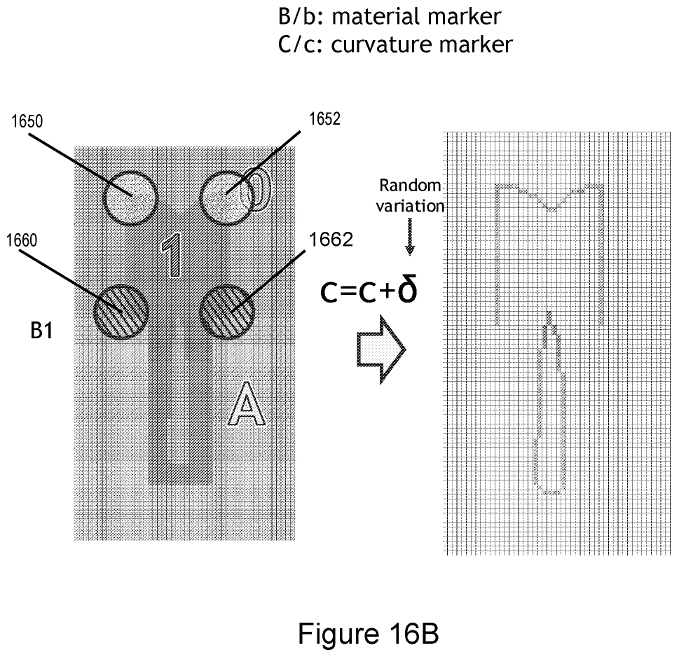

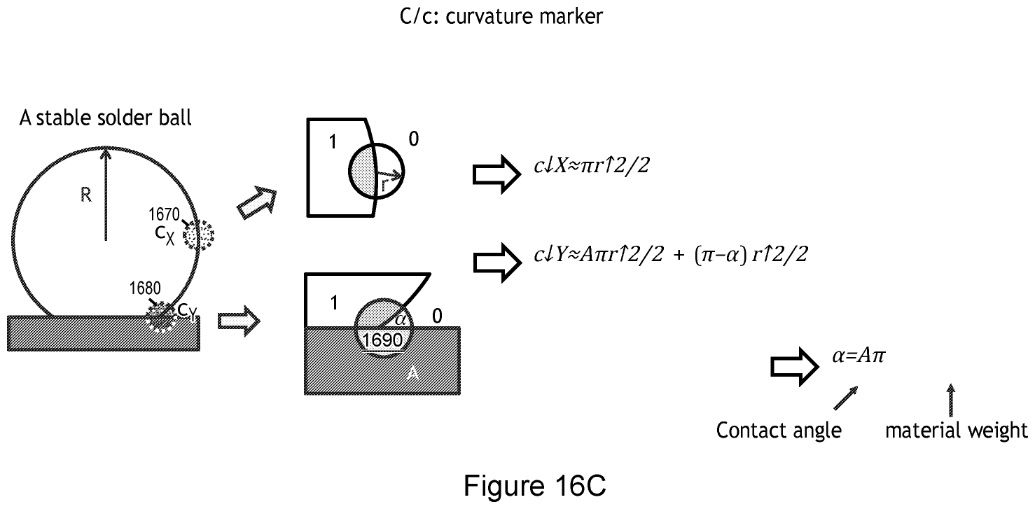

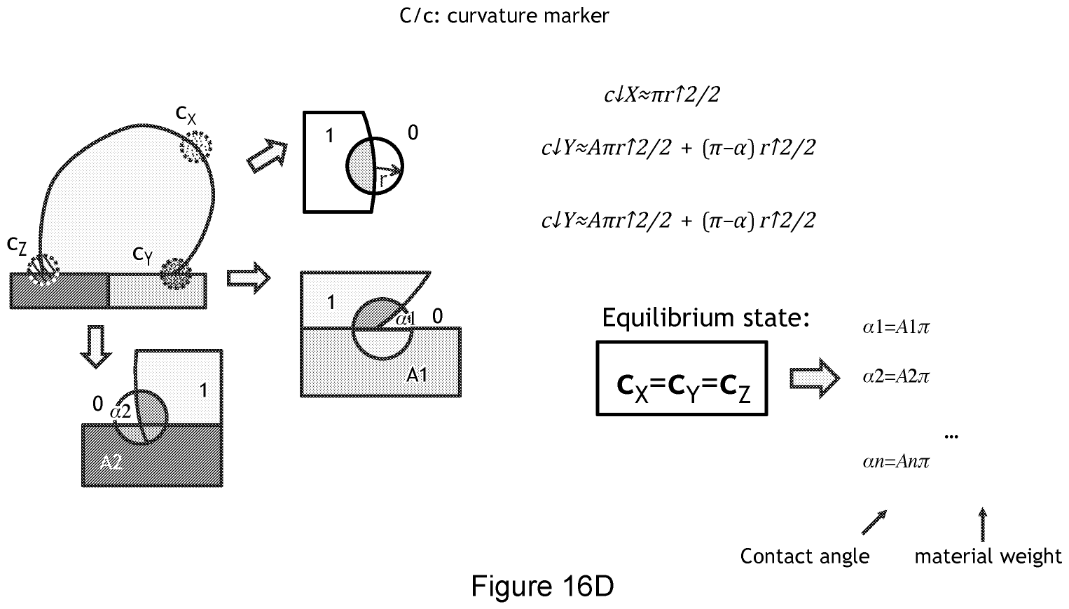

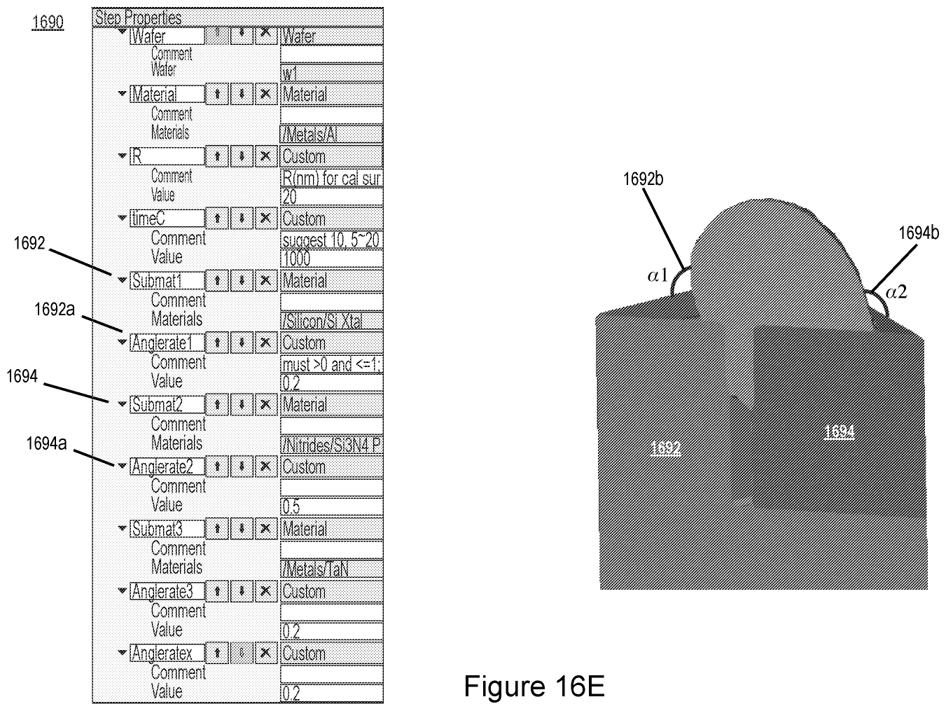

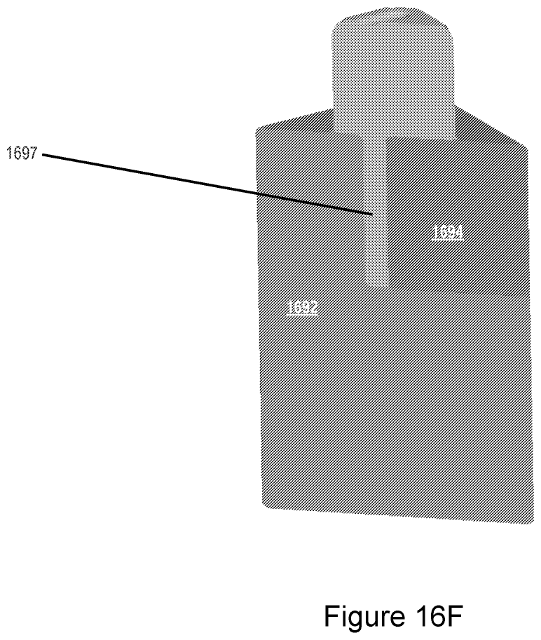

As discussed above, embodiments may use a voxel-based modeling approach to create a 3D model of the semiconductor device being virtually fabricated. The voxels identify one or more materials. In one embodiment, the voxels are loaded into a numpy array. It should be appreciated that the use of other types of arrays instead of a numpy array are also within the scope of the present invention. Binaryzation/Trinaryzation then takes place with each array element indicating a value indicating either air/void, metal or another material (e.g. substrate). For example, air/void voxel elements may be assigned a value of 0, metal voxel elements may be assigned a value of 1 and any other locations not corresponding to metal or air may be assigned another value between 0 and 1 which decides the contact angle between the metal and other materials. This other value “A” (the material weight) may be calculated by the desired contact angle α divided by π (as discussed further in FIG. 16C).

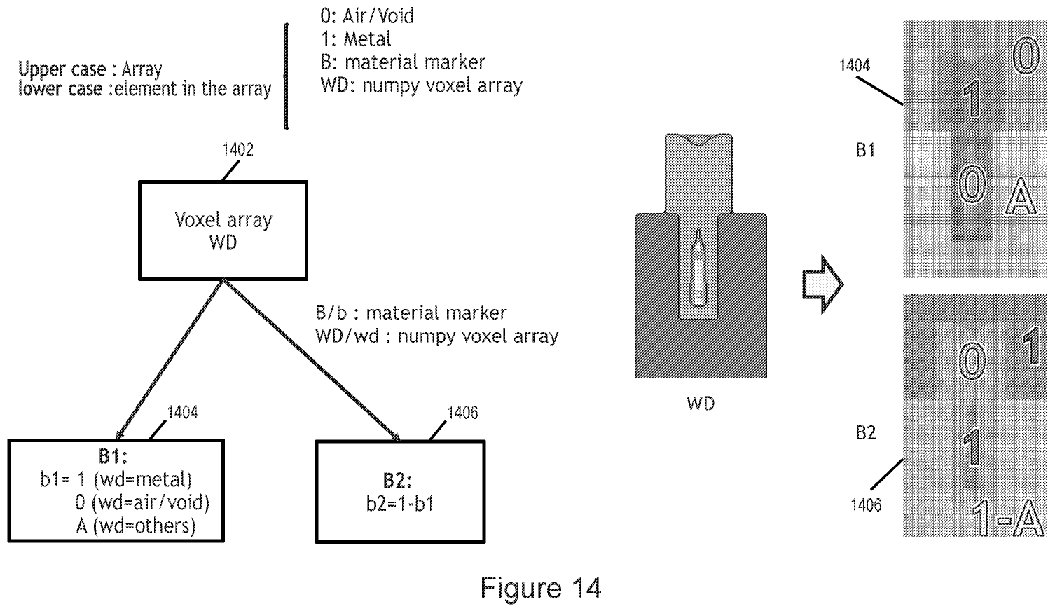

FIG. 14 depicts a voxel numpy array holding arrays of elements that correspond to a portion of the 3D model of FIG. 11 of a trench containing a void in metal following a metal deposition step in an exemplary embodiment. The numpy voxel array WD (1402) hold two arrays B1 (1404) and B2 (1406) holding array element values corresponding to trench 1102, metal 1104, void 1106 and substrate depicted in FIG. 11. It will be appreciated that B2 is a partial inverse/reverse array of the values in B1 (to assist with interface recognition as explained further below) with metal values being replaced by air values and air values being replaced by metal values. For example, if each element b2 in the B2 array is equal to 1-b1, then air voxel values in B1 become 1−0=1 or metal values, metal voxel values become 1−1=0 or air values, and substrate values (assuming a value of 0.5 for A) become 1-0.5=0.5 (and remain unchanged).

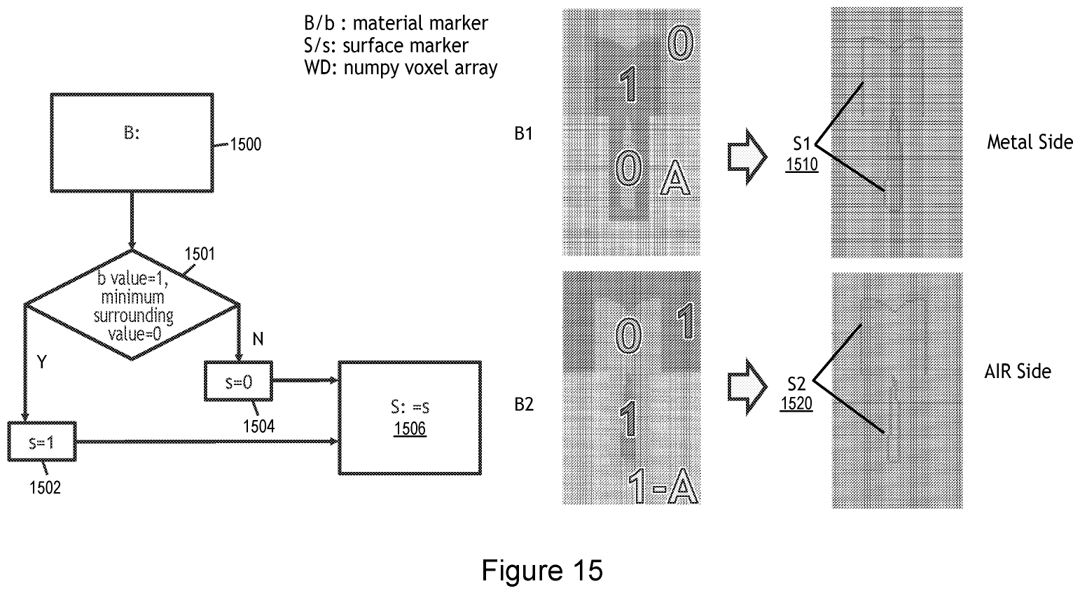

FIG. 15 depicts exemplary interface recognition performed in an exemplary embodiment. The two arrays B1 (1404) and B2 (1406) are used to identify surface markers for the interface of metal and air/void portions of the 3D model. Each array B (i.e. B1 (1404) or B2 (1406)) is examined (step 1500). For each array element b for which the value equals 1, the minimum surround value is examined to determine if the minimum surrounding value is 0 (step 1501). If the minimum surrounding value is 0 (i.e. is a value corresponding to air) (step 1502) then the surface marker element s equals 1 (i.e. the voxel value represents an interface voxel (step 1506). If the minimum surrounding value is not 0 (i.e. is a value corresponding to metal or another material) (step 1504) then the surface marker element s equals 0 (step 1506) (i.e. the voxel value does not represent an interface voxel). Examining each of the array elements in this manner surface markers S1 (1510) and S2 (1520) can be developed to identify the interface between metal and air/void in the model. It will be appreciated that surface markers S1 (1510) and S2 (1520) are very similar and yet not identical due to the implicit nature of voxel representations. During voxel replacement, the metal voxel in metal surface (S1) is moved to air/void surface (S2).

Once the surface markers identifying the interface have been determined embodiments perform a surface curvature calculation at the interface locations. FIGS. 16A-C depict exemplary surface curvature calculation performed during reflow modeling in an exemplary embodiment. The surface curvature calculation is performed to determine the surface curvature of the interface voxels previously identified. As previously discussed, this will enable the simulation of reflow moving from convex areas to fill concave areas. In one embodiment, the surface curvature calculation attempts to count the metal/air/other voxel types within a circle using different weights and a specified radius. For example, as depicted in FIG. 16A, concave shapes such as the concave shape 1602 will have higher metal counts while the convex shape 1604 will have lower metal counts. Similarly, location 1606 at the upper corner of the metal may have a curvature calculation expressed as cₐ=¼*V where V=4/3πR\hat{ }3 if the metal voxels are assigned a value of one while the surrounding air is assigned a value of 0. In contrast, location 1608 at the intersection of the metal with substrate may be expressed as c_{b}=¼*V+A*½*V as half of the calculation circle is filled with substrate and a ¼ with metal and a ¼ with air. The calculations are performed for both metal side C1 and air side C2 (not shown) using the array and reverse array information and corresponding surface marker information. During voxel replacement, metal voxels in the metal surface with minimum curvature (minimum value in C1) are moved to air/void surface with minimum curvature (minimum value in C2).

In one embodiment, the surface curvature calculation accounts for the fact that many surface voxels have the same curvature which presents a problem in differentiating locations with the same curvature. Embodiments perform voxel replacement on a 1 to 1 basis where 1 metal voxel replaces 1 air/void voxel in order to keep metal volume conservative. During voxel replacement, the minimum curvature values for metal are swapped with minimum curvature values for air/void so having the same curvature values creates ambiguity in determining which voxel value to swap since, for example, 2 convex voxels with the same curvature cannot be moved to replace 1 concave air/void voxel. To address this issue embodiments may add small insignificant random variation on the calculated curvature to allow the different locations to be distinguished as depicted in FIG. 16B. For example, locations 1650 and 1652 may have different random variation added to their respective calculated curvatures to allow them to be distinguished from each other. Similarly, locations 1660 and 1662 may also have different random variation added to their respective calculated curvatures. The introduced random variation therefor allows a 1 to 1 replacement to be conducted even when curvature in different locations would otherwise be identical.

As noted above, in some embodiments such as in solder ball formation it may be desirable to control the contact angle at the interface. More particularly, as depicted in FIG. 16C, for the solder ball to be stable, curvature markers c_{X}=c_{Y}. In one embodiment c_{X} (1670) at the midpoint of the side of the solder ball may be calculated as

c_{X}≈πr²/2

while c_{Y} (1680) at the ball/material interface may be calculated as

$${c}_{Y} \approx \frac{A π {r}^{2}}{2} + \frac{( π - α ) {r}^{2}}{2} .$$

and the contact angle α (1690)

α=Aπ

where A is the material weight. The contact angle α can be adjusted by adjusting the substrate material weight A. When A is adjusted from 0 to 1, α from 0 to π can be obtained.

The contact angle at the interface may be different depending upon the type of material in the substrate and the metal will often be in contact with more than one type of substrate material at the same time. Accordingly, in one embodiment, metal contact with different materials with different contact angles may be simulated in the virtual fabrication environment. By assigning different weights for substrate materials, the multiple angles between the metal and the different substrate materials may be obtained. For example, as depicted in FIG. 16D, a stable solder ball may have curvature markers c_{X}, c_{Y} and c_{Z} where

$${c}_{X} \approx π {r}^{2} / 2 , {c}_{Y} \approx \frac{{A}_{1} π {r}^{2}}{2} + \frac{( π - {α}_{1} ) {r}^{2}}{2} and {c}_{Z} \approx \frac{{A}_{2} π {r}^{2}}{2} + \frac{( π - {α}_{2} ) {r}^{2}}{2}$$

In an equilibrium state where c_{X}=c_{Y}=c_{z}. the contact angles may be calculated as:

$${α}_{1} = {A}_{1} π \\ {α}_{2} = {A}_{2} π \\ … \\ {α}_{n} = {A}_{n} π$$

In one embodiment, as depicted in FIG. 16E, the virtual fabrication environment provides a graphical user interface 1690 allowing a user to select the different substrate materials 1692, 1694 and contact angle rate parameters 1692a, 1694a to determine contact angles α₁ (1692b) and α₂ (1694b). The angle rate is marked as An in the above equation, and can be defined from 0 to 1. In one embodiment, when An=0, the contact angle alpha is equal to 0, and when An=1 the contact angle alpha is equal to 180 degrees. So generally, the contact angle A may be defined from 0˜1 instead of using a contact angle from 0 to pi (180 degrees). In one embodiment, the reflow modeling step may support up to five substrate materials at the same time. The ability to specify the different types of substrate also enables the virtual fabrication environment to simulate the capillary effect 1697 that occurs during reflow modeling when metal flows into the seam between two different substrate materials 1692,1694 as depicted in the device structure model shown in FIG. 16F The capillary effect happens in a very narrow seam space. The interaction between contacting surfaces of a liquid and a solid distorts the liquid surface from a planar shape and causes the liquid to rise or fall in a narrow tube.

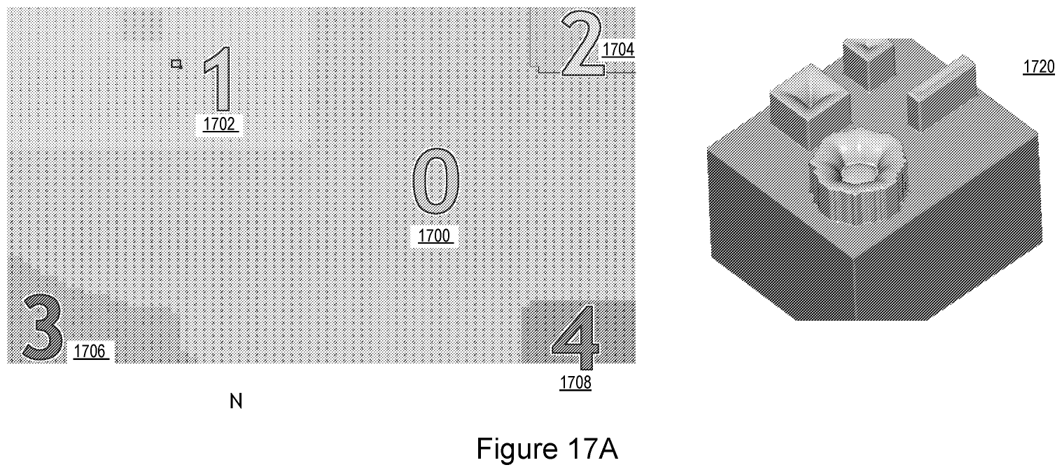

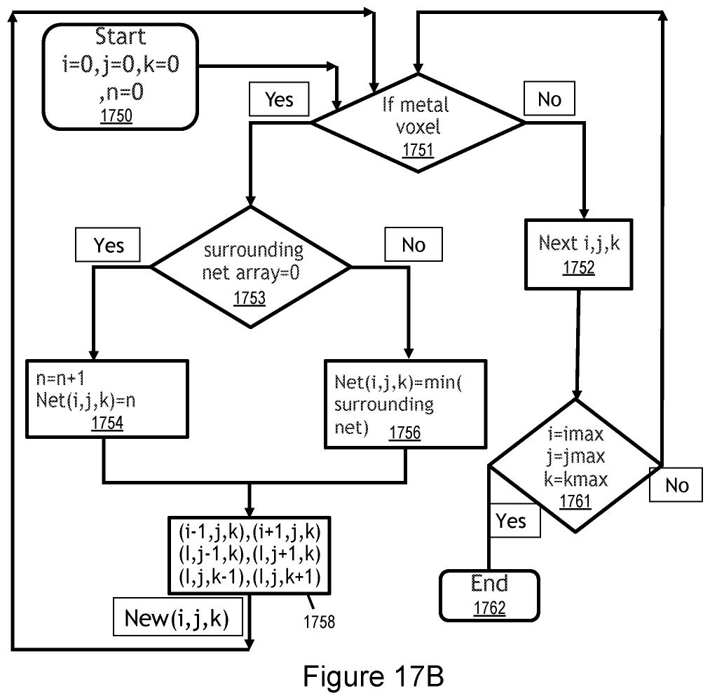

Once the surface curvature calculations have been completed, embodiments perform a net recognition step to make sure that the reflow modeling is confined to a particular “net”. FIGS. 17A-B depict exemplary nets and recognition operations performed during reflow modeling in an exemplary embodiment. FIG. 17A depicts five exemplary nets: 0 (1700), 1 (1702), 2 (1704), 3 (1706) and 4 (1708). Net 0 (1700) represents an insulator while nets 1 (1702), 2 (1704), 3 (1706) and 4 (1708) represent different metal nets in model 1720. The nets are identified from the structural model data by the virtual fabrication environment. Net recognition is performed to make sure that voxel replacement during the metal reflow modeling takes place within the intended net.

FIG. 17 B, depicts a loop through the values of a voxel array with an index initially set to [0,0,0] (X,Y,Z) (step 1750). During each loop, each voxel element is checked to see if the voxel is filled with metal (i.e. if the array element value corresponds to a metal value) (step 1751). If the value is not a metal value (step 1751), the index values are advanced (step 1752) and checked to see if (X, Y, Z) corresponds to [Xmax, Ymax, Zmax] (step 1754). If the end of the array has not been reached, the process iterates and the next voxel element in the array is checked (step 1751). If the value is a metal value (step 1751), a check is performed to see if its surrounding net marker is 0 (step 1753). A 0 surrounding net marker value indicates that this metal voxel is surrounded with non-metal voxels (or is an un-marked metal voxel), and that this metal voxel should be marked with a new net number (step 1754). If the surrounding net marker for the metal voxel is not 0, it means that this metal voxel is surrounded with at least 1 metal voxel which is already marked with a particular net number. The metal voxel is marked as belonging to the same net (step 1756) because it is connected with the marked metal voxel. After the net marking (step 1754 or step 1756), six identical operations are performed for the metal voxel's six neighborhood voxels by a recursion method (step 1758). As a result, after the recursion, all the nearby voxels in the voxel array have been checked and marked with the net number. Voxels with same net number will be recognized as same net in the downstream voxel replacement module. The process iterates until all voxels in the array have been checked (step 1762).

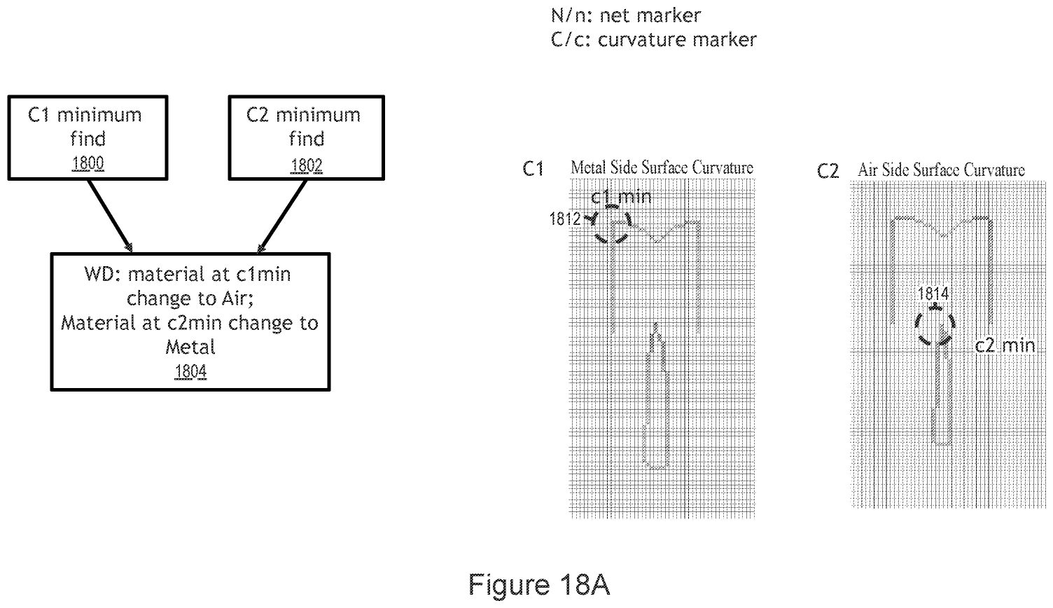

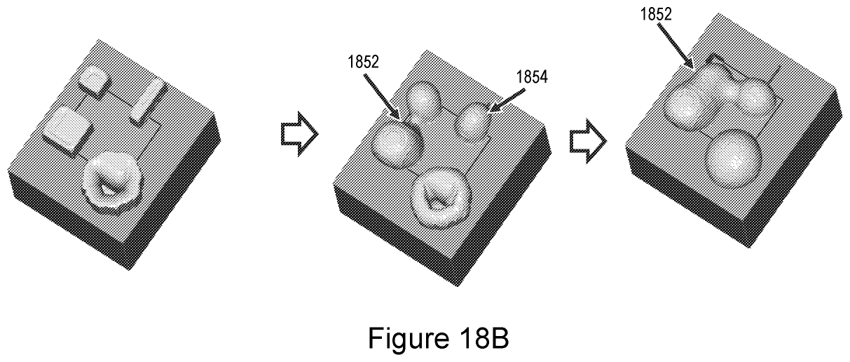

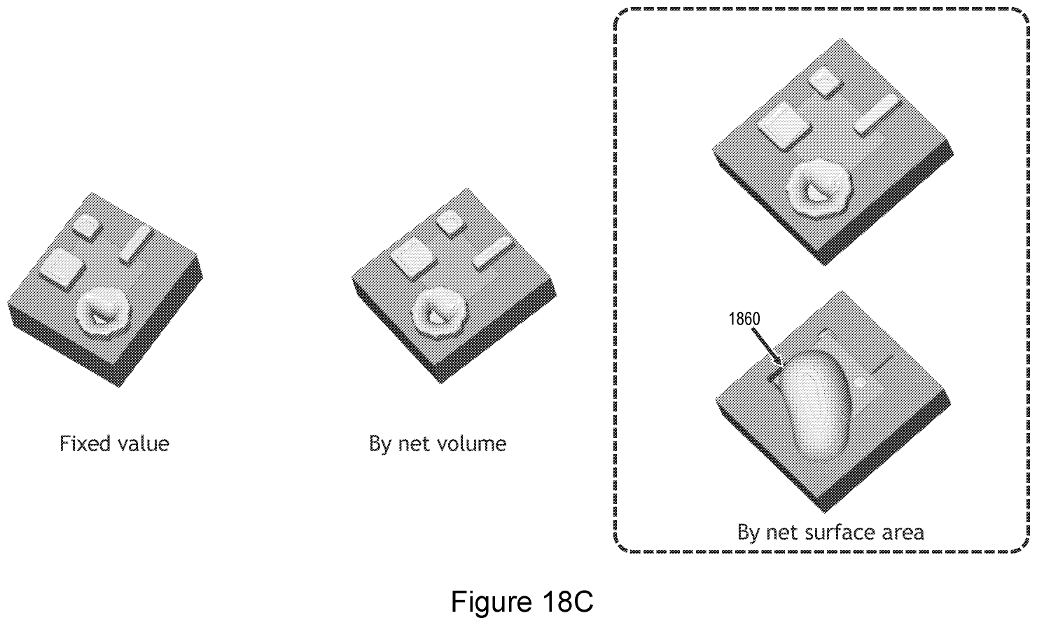

FIG. 18A depicts voxel replacement performed in an exemplary embodiment to model metal reflow. The sequence begins by identifying a minimum value c1 (1812) in C1, (the metal side surface curvature) (step 1800). Then a minimum value c2 (1812) in C2, (the air side surface curvature) is identified (step 1814). Following identification, the material (in the numpy array WD) at the c1 minimum is changed to air while the material at the c2 minimum is changed to metal. This voxel replacement process simulates the flow of metal from the convex portions to the concave portions during metal reflow.

In one embodiment, the reflow modeling step allows a user to simulate metal reflow with multiple patterns and multiple nets. Nets move and nets merge during reflow. By setting different contact angles the movement and merger of the metal reflow may be controlled. FIG. 18B depicts examples of reflow merger 1852 and movement 1854 attainable by setting different contact angles in an exemplary embodiment.

Depending on the problem being solved, different nets need different reflow rates. Embodiments enable the reflow rates to be controlled based on a fixed value, a net volume and/or a net surface area ratio. The fixed values method moves a fixed number of voxels for each net in each cycle (each single loop). The fixed net volume and surface ratio can move a fixed ratio of volume or surface voxels in each reflow cycle. FIG. 18C depicts the effect 1860 of performing reflow modeling based on net surface area ratio in an exemplary embodiment. In many cases of reflow, the thermal absorption should be proportional to the net surface area, in which case using the fixed surface area ratio setting may be preferable. With a fixed surface area ratio, a net with a larger surface area will move and replace more voxels than that of a net with a smaller surface area.

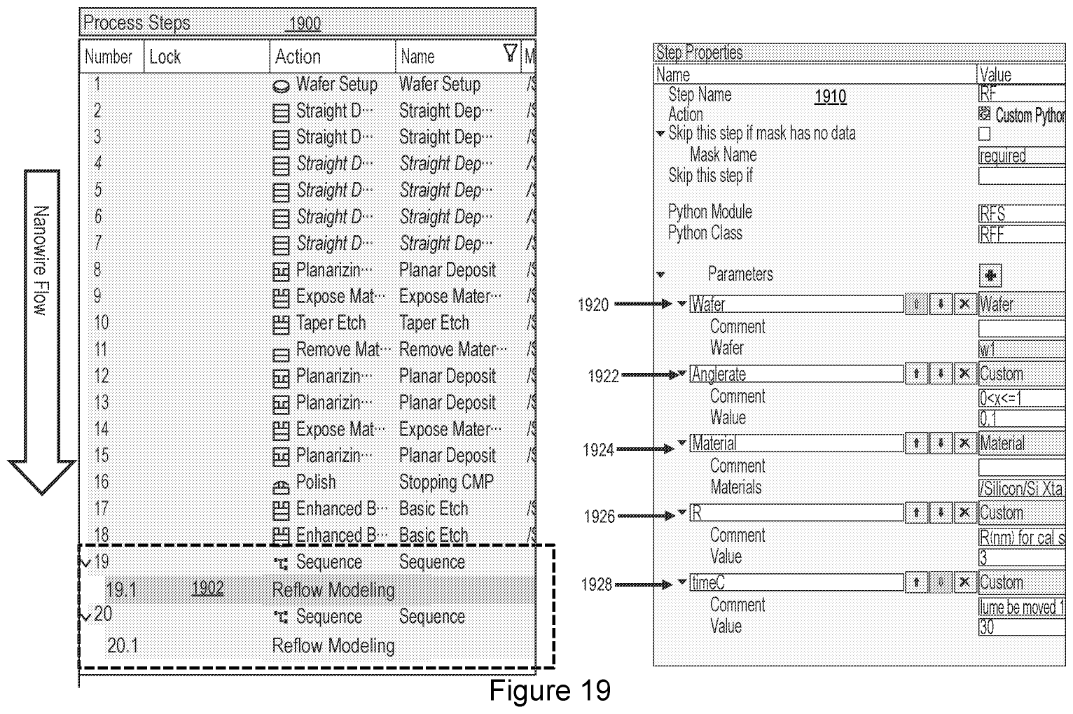

FIG. 19 depicts exemplary user interfaces suitable for adding reflow modeling steps to a process sequence and for selecting parameters for the material reflow of FIGS. 13A and 13B in an exemplary embodiment. The virtual fabrication environment provides a graphical user interface 1900 enabling a user to add a reflow modeling step 1904 to an Si nanowire fabrication process sequence 1902. A graphical user interface 1910 is also provided that enables a user to select parameters for the reflow modeling step added to the process sequence. For example, parameters may include a wafer parameter 1920 defining which wafer to be operated. Parameters may also include a desired contact angle 1922 to be produced and a material parameter 1924 defining the material needing to reflow. Additional parameters may include a radius parameter 1926 used to calculate surface curvature and a TimeC parameter 1928 used to define the total reflow volume for each reflow cycle. For the most accuracy, the reflow modeling step may move only move 1 metal voxel at each loop, but such an approach takes a long time for the reflow evolution. Accordingly, in one embodiment the user is allowed to define appropriate TimeC to increase reflow volume at each cycle to speed up the evolution speed in exchange for somewhat lesser accuracy. It will be appreciated that additional parameters associated with reflow modeling in the virtual fabrication environment may also be selectable by a user and embodiments are not limited to the parameters specifically depicted in graphical user interface 1910.

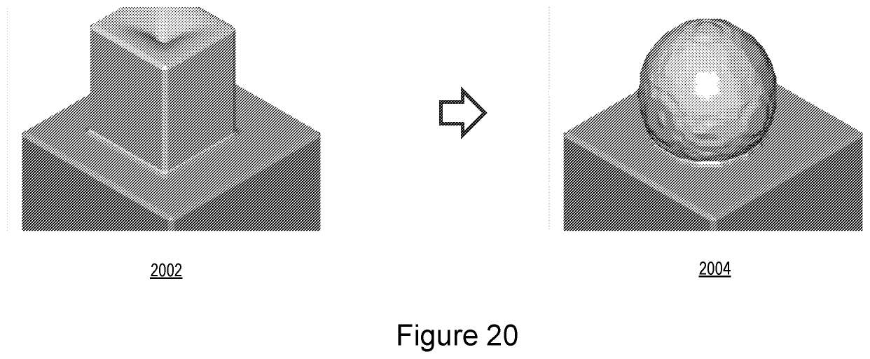

Solder ball formation is an important process in chip package and embodiments enable the modeling of reflow for solder ball formation. FIG. 20 depicts exemplary metal reflow modeled for solder/ball formation in an exemplary embodiment. An initial metal feature 2002 is molded using reflow into a solder ball 2004.

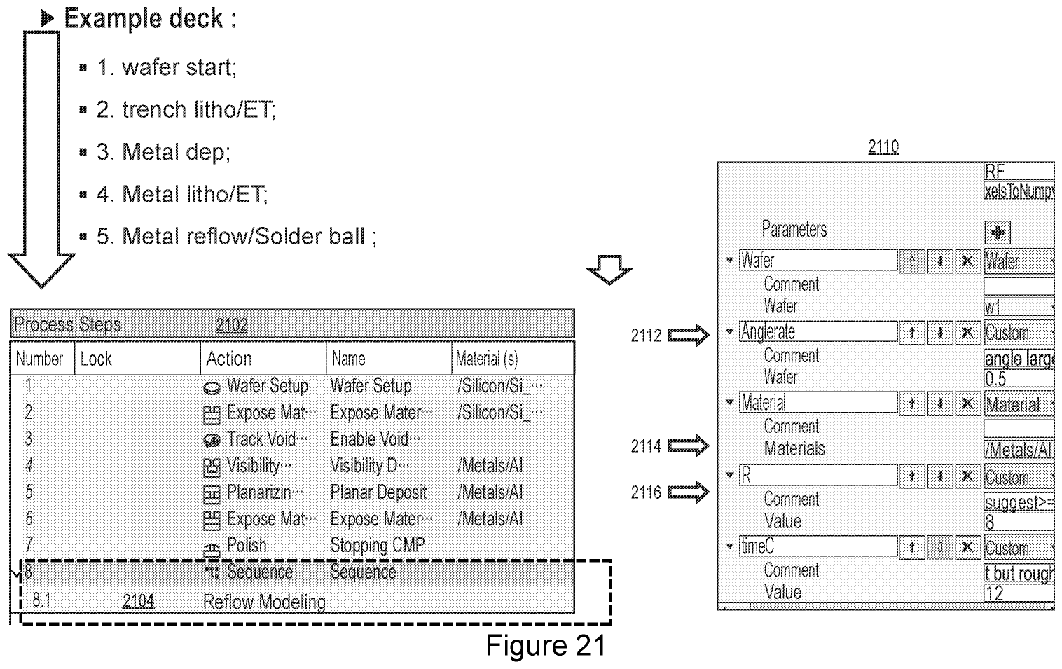

FIG. 21 depicts an exemplary user interface suitable for selecting parameters for the solder/ball formation of FIG. 20. A graphical user interface 2102 is provided that enables a user to add a reflow modeling step 2104 for solder ball formation to the process sequence. A graphical user interface 2110 may enable a user to select parameters associated with the reflow modeling step 2104. For example the graphical user interface 2110 may enable a user to select a control contact angle parameter 2112, a control radius parameter 2114 and a timeC parameter 2116 that controls the reflow volume per cycle. It will be appreciated that other parameters other than those depicted and discussed herein that are associated with reflow modeling step 2104 may also be selectable via graphical user interface 2110 and the invention is not limited to the specifically displayed parameters.

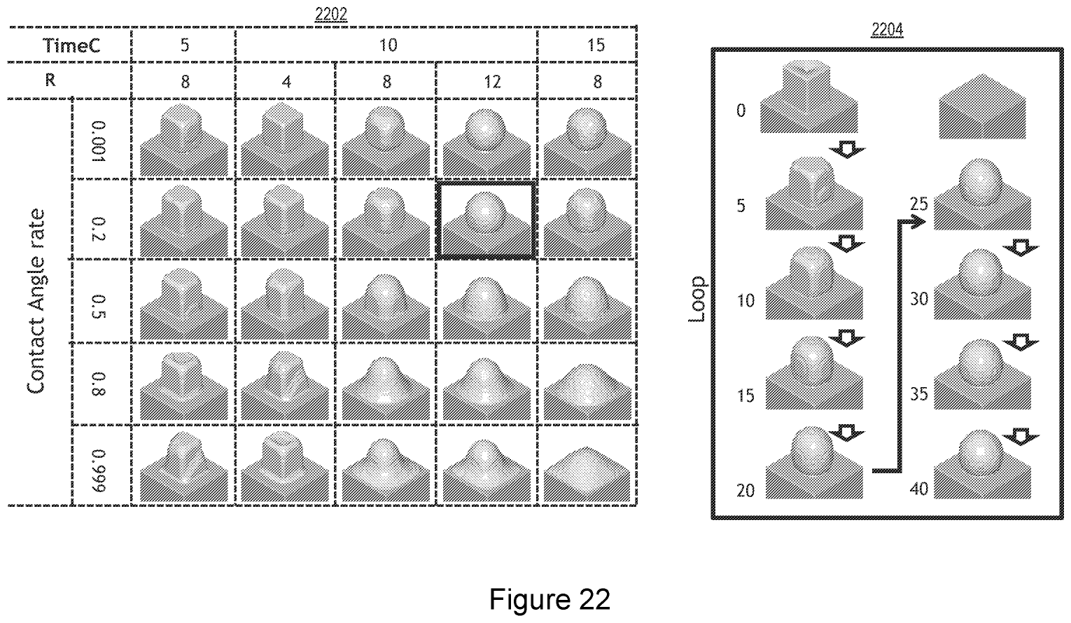

FIG. 22 depicts exemplary DOE results for solder/ball formation in an exemplary embodiment. A table 2202 depicts the various results for solder ball formation in a DOE based on different radius, timeC and contact angle parameters selected for the reflow modeling step 2104. Upon examination it would appear that a contact angle rate of 0.001, a radius of 8 and a TimeC parameter of 15 yields the best looking solder ball in this DOE. Table 2204 shows exemplary results for the reflow modeling used to create the solder ball at different loop intervals with the reflow modeling completing by loop 40.

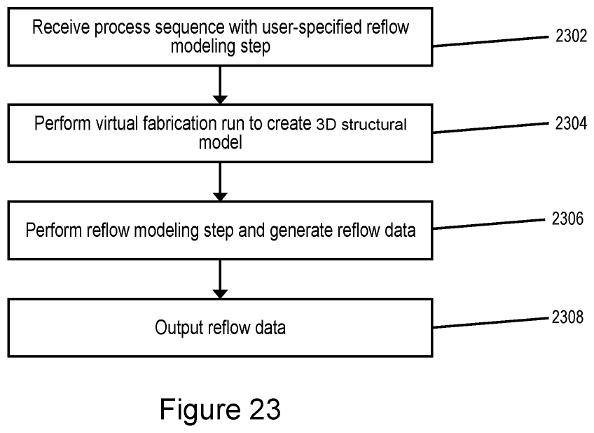

FIG. 23 depicts an exemplary sequence of steps performed in the virtual fabrication environment to perform reflow modeling in an exemplary embodiment. The sequence begins by receiving in a virtual fabrication environment a process sequence that includes a reflow modeling step (step 2302). A virtual fabrication run is performed using the process sequence and generates a 3D structural model (step 2304). The reflow modeling step is then performed at the indicated position in the process sequence and generates reflow data (step 2306) such as results of the reflow modeling operations described herein. The reflow data is then output (step 2306). For example, the reflow data may be exported or displayed. In one embodiment, the reflow data may be displayed in a 3D view of the 3D structural model provided by the virtual fabrication environment.

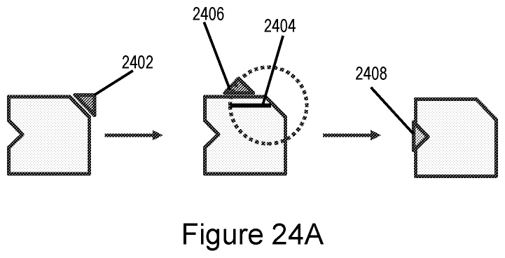

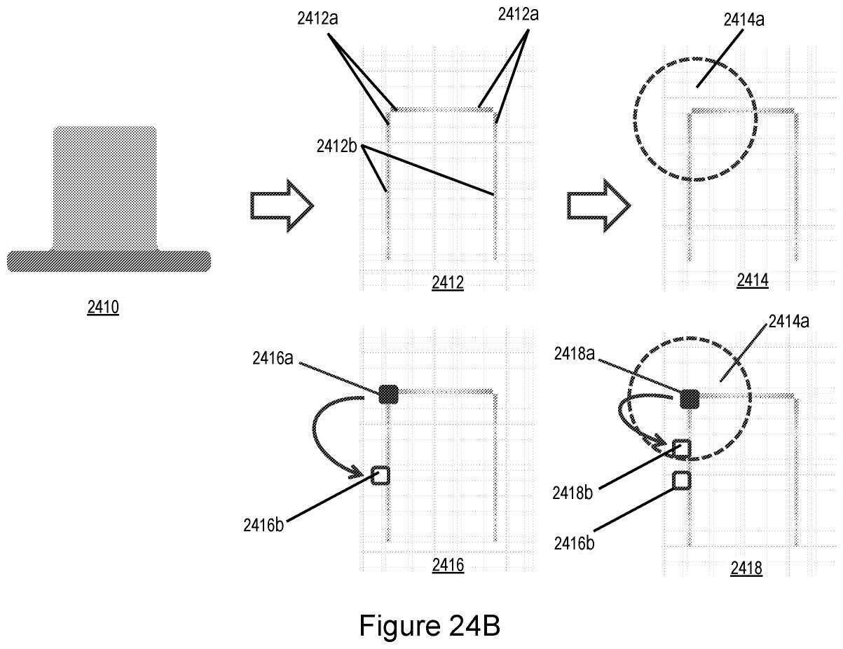

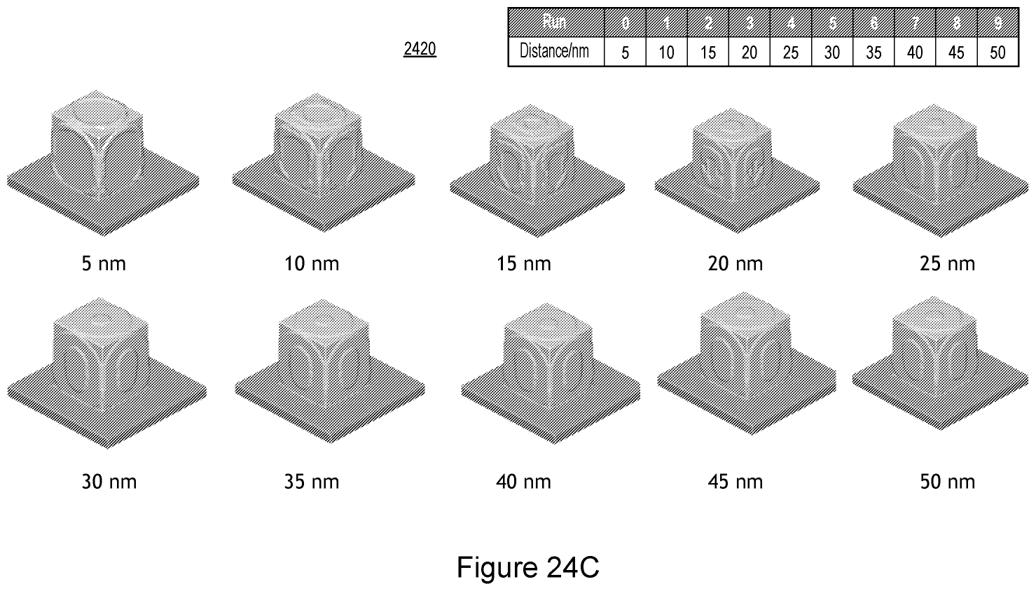

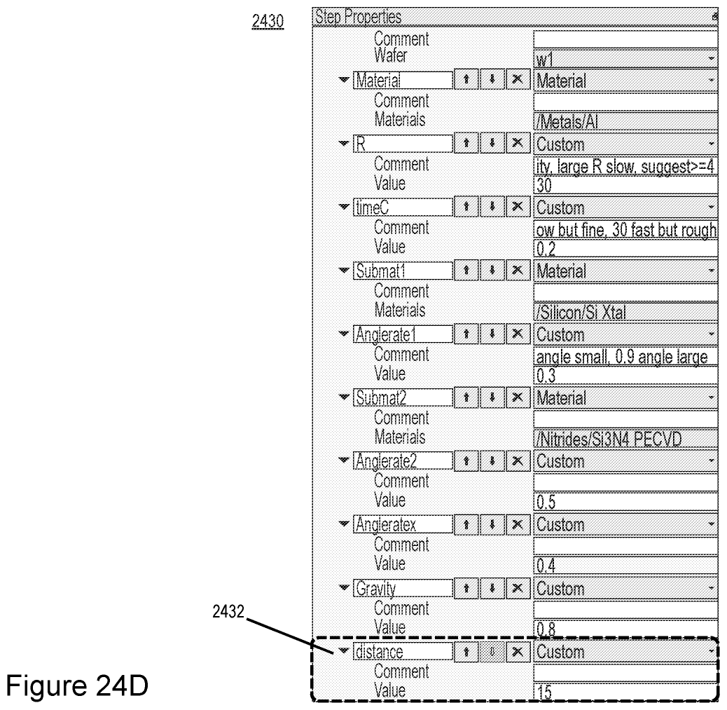

In one embodiment, the reflow modeling step may be further refined to control the distance over which reflow modeling takes place. Local distance control allows the voxel curvature to be locally sorted so that the voxels are moved from a local convex feature to a local concave feature within a constrained distance. With this approach voxel movement is confined to a local area with each iteration of the loop which is a more realistic result as metal can only flow so far within a certain time. The end result of the simulation may end up being the same as described above given enough iterations but the user is given more granular information as to how the reflow evolves over time. Local distance control in exemplary embodiments is graphically depicted in FIGS. 24A-24D.

FIG. 24A depicts a convex feature 2402 being removed and the initial radius/limit 2404 of movement of the reflow material for local concave fill at an initial location 2406. On a subsequent iteration of the reflow modeling loop reflow that removes another convex feature, concave fill can take place at location 2408 when that location is within range of the newly removed convex feature. In one embodiment, a small random variation is added to the curvature results during the curvature calculation step that does not change the curvature value order (ranking) between two surface locations with curvature difference but ensures that when two location have same curvature, they will be given a random order so that a concave feature may always be identified. In another embodiment, a limitation of the replacement voxel count may be specified, for example by limiting voxel replacement so that only the top 10% of convex voxels are moved to fill in the bottom 10% of concave locations, with the result that the overall curvature difference range becomes smaller.

Local distance control is further depicted in FIG. 24B. For an initial metal feature 2410, surface finding and curvature calculation 2412 is performed as described above to identify convex 2412a and concave 2412b features/locations. Local distance control 2414 then examines a range 2414a around each convex feature being removed. This distance radius controls the maximum distance in which local concave locations undergo reflow. Without distance control 2416, a convex feature 2416a would be removed and the concave feature 2416b would undergo reflow fill. With local distance control 2418, the convex feature 2418a is removed and a local concave feature 2418b within the range 2414a undergoes reflow fill. On a subsequent iteration the concave feature 2416b may undergo reflow as it comes within range of a closer convex feature being removed. Accordingly, the use of local distance control provides more granular information regarding the way in which the reflow flow evolves over time.

FIG. 24C provides a graphical depiction 2420 of the results of a DOE showing the effect of controlling voxel movement over different distances. For example, if the reflow being modeled is slow, a 5 nm distance may be appropriate. In contrast, if the reflow being modeled is faster, a 50 nm distance indicating may be more accurate for the reflow modeling step.

In one embodiment, the virtual fabrication environment may provide a graphical user interface which includes a user-selectable parameter in the reflow modeling step by which the user can indicate a preference for local distance control. FIG. 24D depicts a graphical user interface 2430 which includes a user-selectable parameter 2432 for local distance control.

It should be appreciated that the reflow modeling described herein may be provided in a number of different ways. For example, in one embodiment, the graphical user interfaces and some or all of the associated code for performing reflow modeling may be integrated into the virtual fabrication environment. In another embodiment, the graphical user interface and some or all of the associated code for performing reflow modeling may be provided via a plug-in or other external executable application or process that interacts with the virtual fabrication environment.

In an embodiment, the reflow distance, either from a user-supplied parameter or a pre-defined distance, is used to create a local array of voxels, then local curvature is filtered and voxel replacement occurs locally to perform a local concave fill within the specified distance of a local convex feature being removed.

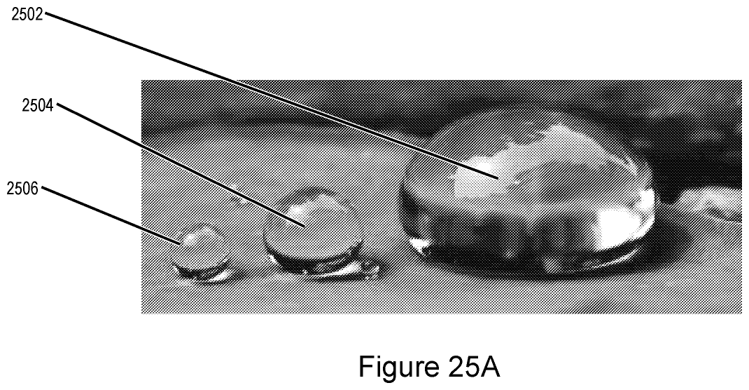

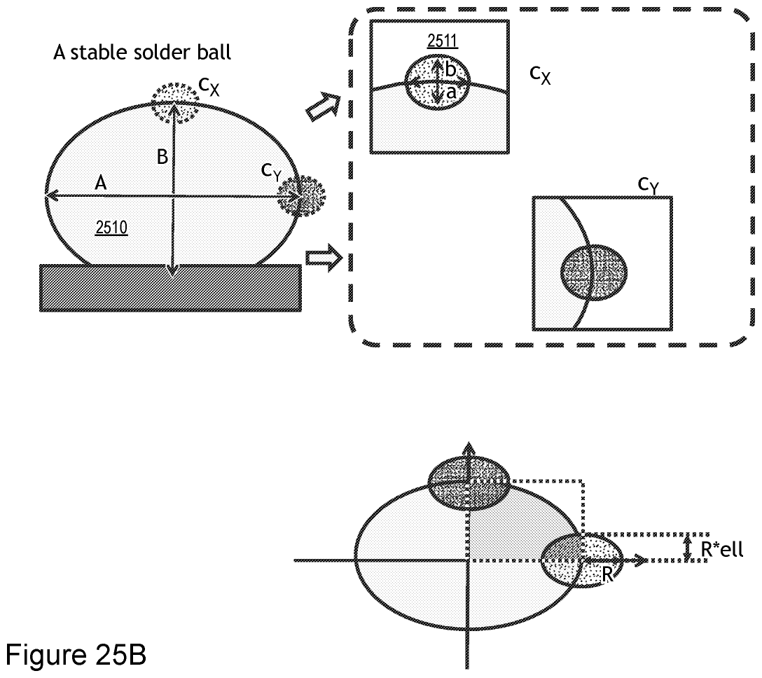

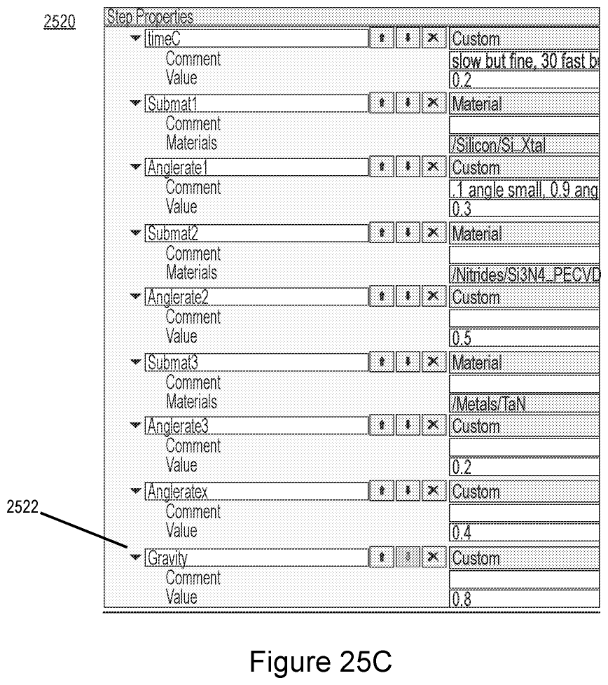

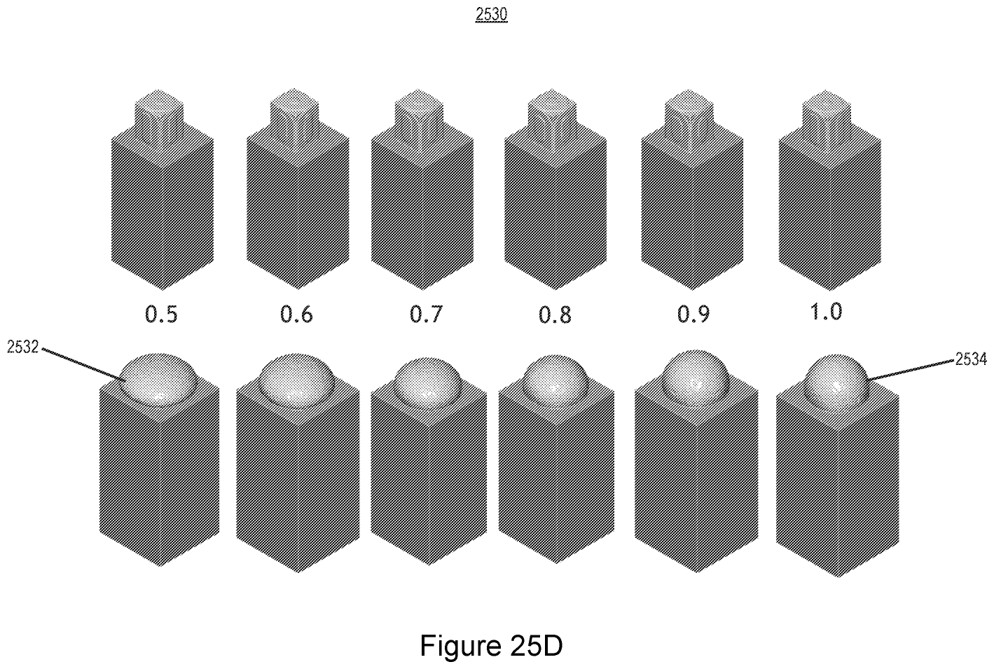

In an embodiment, the reflow modeling step also accounts for the effect of gravity on the surface curvature calculation in single and multiple nets. More particularly, gravity changes what would otherwise be a spherical shape of the reflow material into an ellipsoid. For example, as depicted in FIG. 25A, in the physical fab, a solder ball may have more of an ellipsoid shape 2502 rather than a rounder shape 2504 or a perfect sphere shape 2506 depending on volume and its material.

In an embodiment, a stable solder ball 2510 may have A and B radii and surface curvatures cₓ, c_{y} where cₓ=c_{y}. An ellipsoid 2511 with radii a,b as shown may be used to calculate the curvature for cₓ=c_{y} using a gravity coefficient parameter that changes the vertical/horizontal ratio of the ellipsoid. In one embodiment, the effect of gravity may be expressed as Gravity=b/a=R*ell/R where ell is the retrieved gravity coeffeicient and R is the ellipsoid radius as graphically depicted in FIG. 25B. It will be appreciated that a smaller gravity coefficient will lead to a flatter shape for the solder ball.

In an embodiment, as depicted in FIG. 25C, the gravity coefficient parameter 2522 for a reflow modeling step may be supplied via a graphical user interface 2520 in the virtual fabrication environment.

FIG. 25D depicts a result 2530 of an exemplary DOE performing a reflow modeling step in which the gravity coefficient is adjusted between 0.5 to 1.0. to simulate a range of effects from high gravity impact to low gravity impact. As noted, the resulting solder ball varies between plate-like 2532 and a perfect sphere 2534. In some embodiments, the value selected by the user may be based on silicon data gathered from fabrication runs in a physical fab.

In one embodiment, the effect of gravity on multiple nets may be calculated during the reflow modeling step. More particularly, the effect of gravity may be determined based on the use of a gravity coefficient, metal density and net volume (volume*density*g). In the case of a solder ball, for a particular material, a small net volume leads to a rounder shape while a larger net volume leads to a flatter plate-like shape. For example, if b/a=f(v) and f (v)=1/(e\hat{ }((v−V_{ref})/D)+1), the gravity effect of a particular metal may be calibrated once V_{ref} and D are set properly. In sequence, after capturing the gravity value (gravity=V_{ref}) and D, net volume is calculated after the net recognition step, and curvature is calculated using the net volume information. In this manner, gravity is considered with net volume and metal density to realize different ellipsoids with different volumes. Increasing V_{ref} leads to rounder shapes while increasing D leaves to flatter shapes.

Although the description herein has focused on voxel-based models simulated by the virtual fabrication environment, it should be appreciated that embodiments of the present invention are not so limited. In some embodiments, the techniques described herein for reflow modeling may be applied in virtual fabrication environments that do not rely on voxel-based representation of models

Portions or all of the embodiments of the present invention may be provided as one or more computer-readable programs or code embodied on or in one or more non-transitory mediums. The mediums may be, but are not limited to a hard disk, a compact disc, a digital versatile disc, a flash memory, a PROM, a RAM, a ROM, or a magnetic tape. In general, the computer-readable programs or code may be implemented in any computing language.

Since certain changes may be made without departing from the scope of the present invention, it is intended that all matter contained in the above description or shown in the accompanying drawings be interpreted as illustrative and not in a literal sense. Practitioners of the art will realize that the sequence of steps and architectures depicted in the figures may be altered without departing from the scope of the present invention and that the illustrations contained herein are singular examples of a multitude of possible depictions of the present invention.

The foregoing description of example embodiments of the invention provides illustration and description, but is not intended to be exhaustive or to limit the invention to the precise form disclosed. Modifications and variations are possible in light of the above teachings or may be acquired from practice of the invention. For example, while a series of acts has been described, the order of the acts may be modified in other implementations consistent with the principles of the invention. Further, non-dependent acts may be performed in parallel.

We claim:

1. A non-transitory medium holding computer-executable instructions for performing reflow modeling in a virtual fabrication environment, the instructions when executed causing at least one computing device to:
receive a selection of a process sequence in a process editor for a semiconductor device structure to be virtually fabricated, the process sequence including a user-specified reflow modeling step, the reflow modeling step indicating a point during the process sequence for reflow modeling to be performed;
perform with the computing device a virtual fabrication run that models an integrated process flow used to physically fabricate the semiconductor device structure by using the process sequence and 2D design data to simulate patterning, material addition and/or material removal steps performed to physically fabricate the semiconductor device structure, the virtual fabrication run:
executing the process sequence up until the reflow modeling step, the executing building a 3D structural model of the semiconductor device structure, the 3D structural model predictive of a result of a physical fabrication of the semiconductor device structure, and
performing the reflow modeling step within a region of the 3D structural model, the reflow modeling step generating reflow data; and
outputting the reflow data generated from the reflow modeling step.

2. The medium of claim 1 wherein, the reflow modeling step performs interface recognition.

3. The medium of claim 1 wherein, the reflow modeling step performs surface curvature calculation.

4. The medium of claim 1 wherein, the reflow modeling step performs net recognition.

5. The medium of claim 1 wherein the reflow modeling step further performs voxel replacement in the 3D structural model.

6. The medium of claim 1 wherein the reflow modeling step includes user-specified parameters indicative of a wafer to be operated on and a material for reflow.

7. The medium of claim 1 wherein the reflow modeling step includes a user-specified parameter indicative of a radius to be used for surface curvature calculation.

8. The medium of claim 1 wherein the reflow modeling step includes a user-specified parameter indicative of a surface contact angle.

9. The medium of claim 1 wherein the reflow modeling step is iteratively performed and includes a user-specified parameter defining a reflow total volume for each cycle.

10. The medium of claim 1 wherein the reflow modeling step simulates metal reflow to repair a void in a via or trench caused by metal deposition.

11. The medium of claim 1 wherein the reflow modeling step simulates metal reflow for bump/solder ball formation.

12. The medium of claim 1 wherein the reflow modeling step simulates S1 reflow for S1 nanowire formation.

13. The medium of claim 1 wherein the reflow modeling step simulates thermal reflow for lense formation or surface smoothing for planarization material.

14. The medium of claim 1 wherein the reflow modeling step performs local distance control of reflow modeling.

15. The medium of claim 14 wherein the reflow modeling step includes a user-specified parameter for local distance control of reflow modeling.

16. The medium of claim 1 wherein the reflow modeling step simulates the effect of gravity during reflow.

17. The medium of claim 16 wherein the reflow modeling step includes a user-specified gravity parameter.

18. The medium of claim 1 wherein the reflow modeling step includes multiple contact angles for multiple materials.

19. The medium of claim 18 wherein the reflow modeling step includes user-specified parameters for multiple contact angles for multiple materials.

20. The medium of claim 1 wherein the output reflow data is displayed in a 3D view.

21. A computing device-implemented method for performing reflow modeling in a virtual fabrication environment, comprising:
receiving a selection of a process sequence in a process editor for a semiconductor device structure to be virtually fabricated, the process sequence including a user-specified reflow modeling step, the reflow modeling step indicating a point during the process sequence for reflow modeling to be performed;
performing with the computing device a virtual fabrication run that models an integrated process flow used to physically fabricate the semiconductor device structure by using the process sequence and 2D design data to simulate patterning, material addition and/or material removal steps performed to physically fabricate the semiconductor device structure, the virtual fabrication run:
executing the process sequence up until the reflow modeling step, the executing building a 3D structural model of the semiconductor device structure, the 3D structural model predictive of a result of a physical fabrication of the semiconductor device structure, and
performing the reflow modeling step within a region of the 3D structural model, the reflow modeling step generating reflow data; and
outputting the reflow data generated from the reflow modeling step.

22. The method of claim 21 wherein the reflow modeling step further performs voxel replacement in the 3D structural model.

23. The method of claim 21 wherein the reflow modeling step includes one or more of user-specified parameters indicative of a wafer to be operated on and a material for reflow, a user-specified parameter indicative of a radius to be used for surface curvature calculation, and a user-specified parameter indicative of a surface contact angle,

24. The method of claim 21 wherein the reflow modeling step is iteratively performed and includes a user-specified parameter defining a reflow total volume for each cycle.

25. The method of claim 21 wherein the reflow modeling step includes a user-specified parameter for local distance control of reflow modeling.

26. The method of claim 21 wherein the reflow modeling step includes a user-specified gravity parameter to simulate the effect of gravity during reflow.

27. The method of claim 21 wherein the reflow modeling step includes user-specified parameters for multiple contact angles for multiple materials.

28. The method of claim 21, further comprising:
displaying the output reflow data in a 3D view.

29. A system for performing reflow modeling in a virtual fabrication environment, comprising:
at least one materials database; and
at least one computing device equipped with one or more processors and configured to generate a virtual fabrication environment that includes a reflow modeling module that when executed:
receives a selection of a process sequence in a process editor for a semiconductor device structure to be virtually fabricated, the process sequence including a user-specified reflow modeling step, the reflow modeling step indicating a point during the process sequence for reflow modeling to be performed;
performs with the computing device a virtual fabrication run that models an integrated process flow used to physically fabricate the semiconductor device structure by using the process sequence and 2D design data to simulate patterning, material addition and/or material removal steps performed to physically fabricate the semiconductor device structure, the virtual fabrication run:
executing the process sequence up until the reflow modeling step, the executing building a 3D structural model of the semiconductor device structure using data from the materials database, the 3D structural model predictive of a result of a physical fabrication of the semiconductor device structure, and
performing the reflow modeling step within a region of the 3D structural model, the reflow modeling step generating reflow data; and
outputs the reflow data.

30. The system of claim 29 further comprising:
a display surface in communication with the at least one computing device, the display surface configured to display the reflow data.
